(19) United States
(12) Patent Application Publication
(10) Pub. No.: US 2025/0310662 A1
(43) Pub. Date: Oct. 2, 2025

(54) PHOTODETECTION ELEMENT, TIMING GENERATOR, AND AD CONVERTER

(71) Applicant: SONY SEMICONDUCTOR SOLUTIONS CORPORATION, KANAGAWA (JP)

(72) Inventor: MASAKI SAKAKIBARA, KANAGAWA (JP)

(21) Appl. No.: 18/864,019

(22) PCT Filed: Apr. 18, 2023
(86) PCT No.: PCT/JP2023/015422

§ 371 Date: Nov. 8, 2024

(30) Foreign Application Priority Data
May 17, 2022 (JP) 2022-081095

(51) Int. Cl. H04N 25/709; H03M 1/00; H04N 25/76; H04N 25/771; H04N 25/78

(52) U.S. Cl. CPC H04N 25/709; H03M 1/002; H04N 25/771; H04N 25/7795; H04N 25/78

(57) ABSTRACT

To reduce power consumption. A photodetection element includes a plurality of pixels, in which each of the plurality of pixels includes: a physical signal acquisition unit that acquires a physical signal; a comparison unit that compares a physical signal acquired by the physical signal acquisition unit with a reference signal; a signal accumulation floating unit that is electrically connected to one end of the comparison unit; a signal detection unit that is electrically connected to the signal accumulation floating unit and detects a comparison result of the comparison unit; a signal amplification unit that amplifies a detection result of the signal detection unit; a signal storage unit that stores a time code; a signal input/output unit that inputs and outputs a time code; and a signal control unit that performs control to store a time code output from the signal input/output unit in the signal storage unit on the basis of the comparison result, and outputs, to the signal input/output unit, a time code of the time when the comparison result is inverted, the time code being stored in the signal storage unit, and at least two or more of the pixels operate in parallel.

### TECHNICAL FIELD

Embodiments according to the present disclosure relate to a photodetection element, a timing generator, and an AD converter.

### BACKGROUND ART

There is a case where an analog to digital converter (ADC) is provided on the signal reading side of a photodetection element (see Patent Documents 1 to 3).

### CITATION LIST

### Patent Document

Patent Document 1: WO 2016/136448 A
Patent Document 2: WO 2018/037902 A
Patent Document 3: WO 2017/119220 A

### SUMMARY OF THE INVENTION

### Problems to be Solved by the Invention

However, power reduction of the ADC is required.

Therefore, the present disclosure provides a photodetection element, a timing generator, and an AD converter that can reduce power consumption.

### Solutions to Problems

In order to solve the problem described above, according to the present disclosure, provided is a photodetection element including
a plurality of pixels, in which
each of the plurality of pixels includes:
a physical signal acquisition unit that acquires a physical signal;
a comparison unit that compares a physical signal acquired by the physical signal acquisition unit with a reference signal;
a signal accumulation floating unit that is electrically connected to one end of the comparison unit;
a signal detection unit that is electrically connected to the signal accumulation floating unit and detects a comparison result of the comparison unit;
a signal amplification unit that amplifies a detection result of the signal detection unit;
a signal storage unit that stores a time code;
a signal input/output unit that inputs and outputs a time code; and
a signal control unit that performs control to store a time code output from the signal input/output unit in the signal storage unit on the basis of the comparison result, and outputs, to the signal input/output unit, a time code of the time when the comparison result is inverted, the time code being stored in the signal storage unit, and
at least two or more of the pixels operate in parallel.

There may be further provided:
at least two pixel groups each of which detects a physical signal; and
a storage control unit that performs control, for the every pixel group, to store a time code in the signal storage unit and controls whether or not to update a time code stored in the signal storage unit.

The comparison unit may include a transistor including a gate to which a physical signal acquired by the physical signal acquisition unit is input, a source to which the reference signal is input, and a drain electrically connected to the signal accumulation floating unit,
the comparison unit may change a voltage of the signal accumulation floating unit on the basis of a gate-source voltage of the transistor and a threshold of the transistor to enable the signal detection unit to perform detection, and
the signal detection unit may be disposed in a pixel array unit.

There may be further provided a capacitor connected between a reference signal generation unit that generates the reference signal and the source of the transistor.

There may be further provided a connection unit that is connected between the source of the transistor and the gate of the transistor and electrically connects the source of the transistor and the gate of the transistor at a predetermined timing.

The comparison unit may be shared by a plurality of the physical signal acquisition units.

The signal amplification unit may be a positive feedback circuit.

The physical signal acquisition unit, the comparison unit, the signal accumulation floating unit, the signal detection unit, the signal amplification unit, the signal control unit, the signal storage unit, and the signal input/output unit may be disposed across at least two semiconductor chips.

The signal input/output unit may be shared by a plurality of the physical signal acquisition units.

The signal input/output unit may include a flip-flop.

The signal input/output unit may include a tristate inverter.

At least two of the signal storage units may be provided.

At least two of the signal input/output units may be provided correspondingly to respective one of at least two of the signal storage units.

There may be further provided a signal processing unit that performs at least one of subtraction processing between signals stored in at least two of the signal storage units and image processing.

According to the present disclosure, there is provided a timing generator including:
a first circuit, a second circuit, and an arithmetic circuit, in which
the first circuit outputs, on the basis of one input signal, a first output signal obtained by delaying an inversion timing of the input signal, and an activation signal that activates the second circuit,
the second circuit is activated on the basis of the activation signal and outputs a second output signal, and
the arithmetic circuit calculates the first output signal and the second output signal to output a third output signal.

The activation signal may be a first power supply voltage of the second circuit.

The second circuit may be a second power supply voltage of the first circuit in a period in which the second circuit is not activated.

The first circuit and the second circuit include a first positive feedback circuit and a second positive feedback circuit that are connected in series.

According to the present disclosure, there is provided an AD converter including:
a timing generator;
a signal storage unit that stores a time code; and
a signal control unit that performs control to store a time code in the signal storage unit on the basis of the third output signal.

The first circuit may output the first output signal that is inverted at a first timing,
the second circuit may output the second output signal that is inverted at a second timing after the first timing,
the arithmetic circuit may output the third output signal that is inverted at the first timing and the second timing, and
the signal control unit may start storing a time code in the signal storage unit at the first timing, and may stop storing a time code in the signal storage unit at the second timing.

### BRIEF DESCRIPTION OF DRAWINGS

FIG. 1 is a diagram illustrating a schematic configuration of a solid-state imaging device according to the present disclosure.

FIG. 2 is a block diagram illustrating a detailed configuration example of a pixel.

FIG. 3A is a conceptual diagram of constituting the solid-state imaging device by stacking two semiconductor substrates.

FIG. 3B is diagram illustrating a schematic configuration in a case where the solid-state imaging device is constituted by stacking two semiconductor substrates.

FIG. 4A is a conceptual diagram of constituting the solid-state imaging device by stacking three semiconductor substrates.

FIG. 4B is diagram illustrating a schematic configuration in a case where the solid-state imaging device is constituted by stacking three semiconductor substrates.

FIG. 5 is a diagram illustrating an example of a configuration of a solid-state imaging device according to a first embodiment.

FIG. 6 is a circuit diagram illustrating an example of a configuration of a comparison circuit according to the first embodiment.

FIG. 7 is a circuit diagram illustrating an example of a configuration of a data storage unit according to the first embodiment.

FIG. 8 is a timing chart illustrating an example of operation of the comparison circuit and the data storage unit according to the first embodiment.

FIG. 9 is a circuit diagram illustrating an example of a configuration of the comparison circuit according to a first modification of the first embodiment.

FIG. 10 is a circuit diagram illustrating an example of a configuration of the comparison circuit according to a second modification of the first embodiment.

FIG. 11 is a timing chart illustrating an example of operation of the comparison circuit and the data storage unit according to the second modification of the first embodiment.

FIG. 12 is a circuit diagram illustrating an example of a configuration of the comparison circuit according to a third modification of the first embodiment.

FIG. 13 is a circuit diagram illustrating an example of a configuration of the comparison circuit according to a fourth modification of the first embodiment.

FIG. 14 is a circuit diagram illustrating an example of a configuration of the comparison circuit according to a fifth modification of the first embodiment.

FIG. 15A is a diagram illustrating an example of a pixel group of a pixel array unit according to a sixth modification of the first embodiment.

FIG. 15B is a diagram illustrating one modification of FIG. 15A.

FIG. 16 is a block diagram illustrating an example of a configuration of a timing generator according to a second embodiment.

FIG. 17 is a timing chart illustrating an example of operation of the timing generator according to the second embodiment.

FIG. 18 is a diagram illustrating an example of a configuration of a comparison circuit and a data storage unit according to the second embodiment.

FIG. 19 is a circuit diagram illustrating an example of a configuration of the comparison circuit according to the second embodiment.

FIG. 20 is a diagram illustrating an example of a configuration of the data storage unit according to the second embodiment.

FIG. 21 is a timing chart illustrating an example of operation of the comparison circuit and the data storage unit according to the second embodiment.

FIG. 22 is a diagram illustrating an example of a temporal change of voltage in the comparison circuit according to the second embodiment.

FIG. 23 is a circuit diagram illustrating an example of a configuration of a second circuit according to a first modification of the second embodiment.

FIG. 24 is a circuit diagram illustrating an example of a configuration of the second circuit according to a second modification of the second embodiment.

FIG. 25 is a circuit diagram illustrating an example of a configuration of the second circuit according to a third modification of the second embodiment.

FIG. 26 is a block diagram illustrating an example of a schematic configuration of a vehicle control system.

FIG. 27 is an explanatory diagram illustrating an example of installation positions of an outside-vehicle information detecting unit and an imaging section.

### MODE FOR CARRYING OUT THE INVENTION

Hereinafter, embodiments of a photodetection element, a timing generator, and an AD converter will be described with reference to the drawings. In the following, although the main components of the photodetection element, the timing generator, and the AD converter will be mainly described, but the photodetection element, the timing generator, and the AD converter may have components and functions that are not illustrated or described. The following description does not exclude components and functions that are not depicted or described.

### Schematic Configuration Example of Solid-State Imaging Device

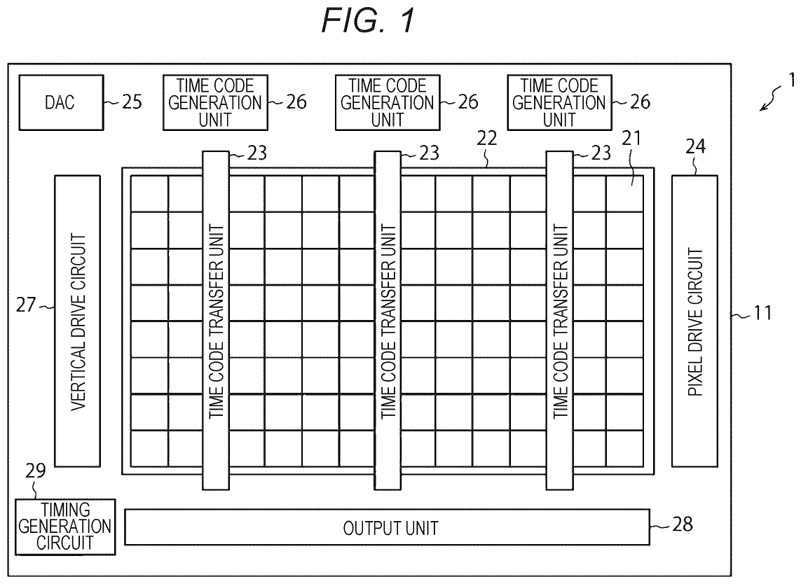

FIG. 1 illustrates a schematic configuration of a solid-state imaging device (photodetection element) according to the present disclosure.

The solid-state imaging device 1 in FIG. 1 includes a pixel array unit 22 in which pixels 21 are arranged in a two-dimensional array on a semiconductor substrate 11 by using, for example, silicon (Si) as a semiconductor. The pixel array unit 22 is also provided with time code transfer units 23 each of which transfers a time code generated by a time code generation unit 26 to each pixel 21. Then, a pixel drive circuit 24, a D/A converter (DAC) 25, the time code generation unit 26, a vertical drive circuit 27, an output unit 28, and a timing generation circuit 29 are formed around the pixel array unit 22 on the semiconductor substrate 11.

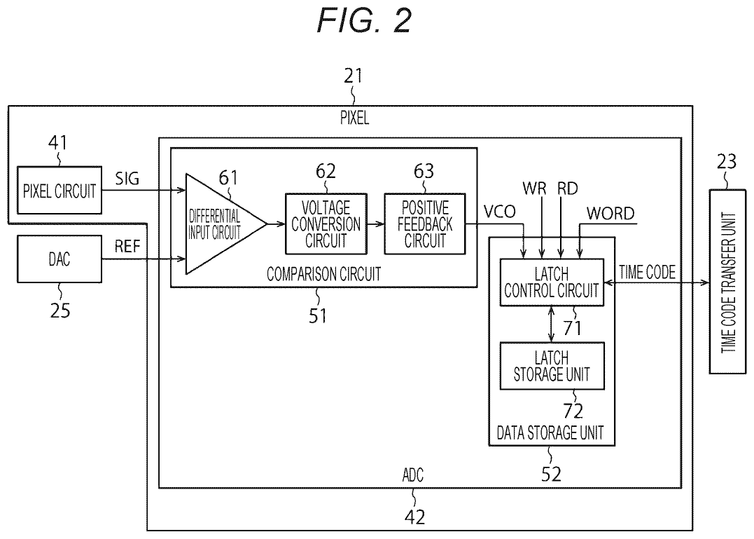

As will be described later with reference to FIG. 2, each of the pixels 21 arranged in a two-dimensional array is provided with a pixel circuit 41 and an ADC 42, and the pixel 21 generates a charge signal corresponding to the amount of light received by a light-receiving element (for example, a photodiode) in the pixel, converts the charge signal into an analog pixel signal SIG, and outputs the analog pixel signal SIG.

The pixel drive circuit 24 drives the pixel circuit 41 (FIG. 2) in the pixel 21. The DAC 25 generates a reference signal (reference voltage signal) REF, which is a slope signal whose level (voltage) monotonously decreases with the lapse of time, and supplies the reference signal REF to each pixel 21. The time code generation unit 26 generates a time code used when each pixel 21 converts the analog pixel signal SIG into a digital signal (AD conversion), and supplies the time code to the corresponding time code transfer unit 23. The time code generation unit 26 is provided in plural numbers for the pixel array unit 22, and in the pixel array unit 22, the time code transfer units 23 are provided as many as the number of the time code generation units 26. That is, the time code generation units 26 and the time code transfer units 23 that transfer the time code generated therein correspond to each other on a one-to-one basis.

The vertical drive circuit 27 performs control to cause the output unit 28 to output the digital pixel signal SIG generated in the pixel 21 in a predetermined order on the basis of a timing signal supplied from the timing generation circuit 29. The digital pixel signal SIG output from the pixel 21 is output from the output unit 28 to the outside of the solid-state imaging device 1. The output unit 28 performs predetermined digital signal processing such as black level correction processing for correcting a black level and correlated double sampling (CDS) processing as necessary, and thereafter, outputs the signal to the outside.

The timing generation circuit 29 includes a timing generator that generates various timing signals and the like, and supplies the generated various timing signals to the pixel drive circuit 24, the DAC 25, the vertical drive circuit 27, and the like.

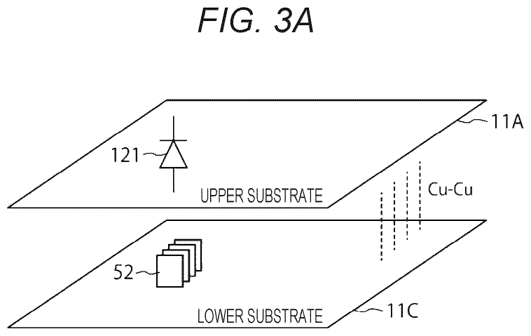

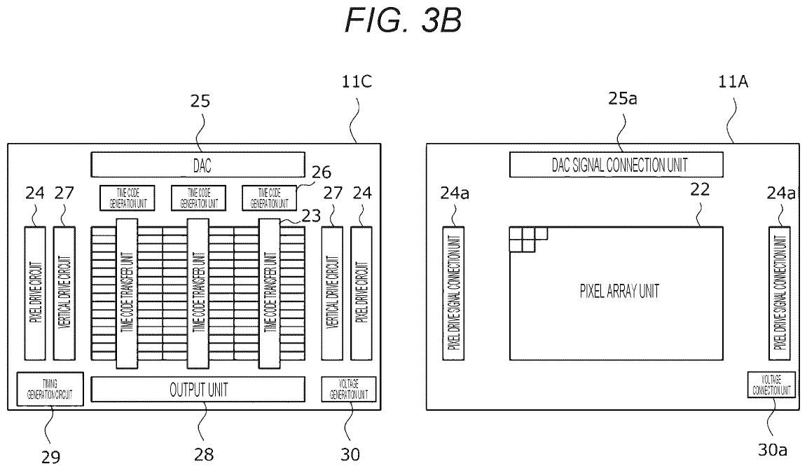

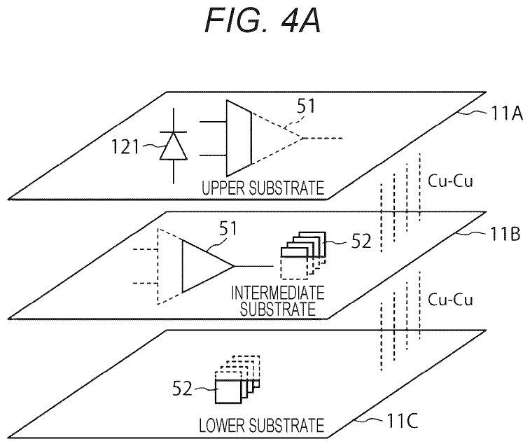

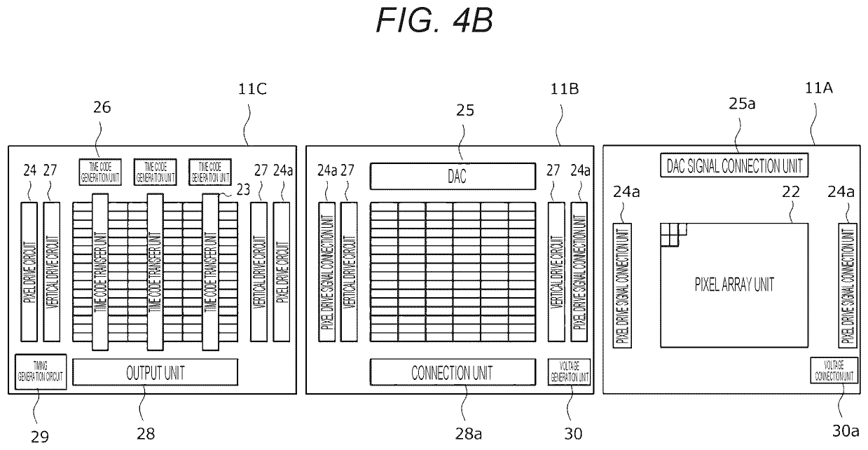

The solid-state imaging device 1 is configured as described above. Note that, in FIG. 1, as described above, it has been described that all the circuits constituting the solid-state imaging device 1 are formed on one semiconductor substrate 11, but as will be described later, by referring to FIGS. 3A, 3B, 4A, and 4B, the circuits constituting the solid-state imaging device 1 may be divided and arranged on a plurality of semiconductor substrates 11.

### Detailed Configuration Example of Pixel

FIG. 2 is a block diagram illustrating a detailed configuration example of the pixel 21.

The pixel 21 includes the pixel circuit 41 and the AD converter (ADC) 42.

The pixel circuit 41 outputs a charge signal corresponding to the amount of received light to the ADC 42 as the analog pixel signal SIG. The ADC 42 converts the analog pixel signal SIG supplied from the pixel circuit 41 into a digital signal.

The ADC 42 includes a comparison circuit 51 and a data storage unit 52.

The comparison circuit 51 compares a reference signal REF supplied from the DAC 25 with the pixel signal SIG, and outputs an output signal VCO as a comparison result signal indicating a comparison result. The comparison circuit 51 inverts the output signal VCO when the reference signal REF and the pixel signal SIG become the same (the same voltage).

The comparison circuit 51 includes a differential input circuit 61, a voltage conversion circuit 62, and a positive feedback circuit (PFB) 63, which will be described later in detail with reference to FIG. 3.

In addition to the input of the output signal VCO from the comparison circuit 51 to the data storage unit 52, from the vertical drive circuit 27, a WR signal indicating that it is a pixel signal writing operation, an RD signal indicating that it is a pixel signal reading operation, and a WORD signal for controlling a reading timing of the pixel 21 during the pixel signal reading operation are supplied from the vertical drive circuit 27. Furthermore, the time code generated by the time code generation unit 26 is also supplied via the time code transfer unit 23.

The data storage unit 52 includes a latch control circuit 71 that controls the writing operation and the reading operation of the time code on the basis of the WR signal and the RD signal, and a latch storage unit 72 that stores the time code.

In the writing operation of the time code, the latch control circuit 71 stores the time code, which is supplied from the time code transfer unit 23 and updated every unit time, in the latch storage unit 72 while a Hi (High) output signal VCO is input from the comparison circuit 51. Then, when the reference signal REF and the pixel signal SIG become the same (voltage) and the output signal VCO supplied from the comparison circuit 51 is inverted to Lo (Low), writing (updating) of the supplied time code is stopped, and the time code finally stored in the latch storage unit 72 is held in the latch storage unit 72. The time code stored in the latch storage unit 72 indicates a time at which the pixel signal SIG and the reference signal REF become equal to each other, and represents data indicating that the pixel signal SIG has been the reference voltage at that time, that is, a digitized value of the amount of light.

After the sweep of the reference signal REF is completed and the time codes are stored in the latch storage units 72 of all the pixels 21 in the pixel array unit 22, the operation of the pixels 21 is changed from the writing operation to the reading operation.

In the time code reading operation, on the basis of the WORD signal for controlling the read timing, the latch control circuit 71 outputs the time code (digital pixel signal SIG) stored in the latch storage unit 72 to the time code transfer unit 23 when the pixel 21 reaches its own reading timing. The time code transfer unit 23 sequentially transfers the supplied time code in the column direction (vertical direction) and supplies the time code to the output unit 28.

Hereinafter, in order to distinguish from the time code written in the latch storage unit 72 in the writing operation of the time code, digitized pixel data is also referred to as AD converted pixel data, the digitized pixel data indicating that the pixel signal SIG has been the reference voltage at the time, the pixel signal SIG being an inverted time code of the time when the output signal VCO read from the latch storage unit 72 in the time code reading operation is inverted.

### First Example of Plural-Substrate Configuration

FIG. 3A is a conceptual diagram of constituting the solid-state imaging device by stacking two semiconductor substrates. FIG. 3B is diagram illustrating a schematic configuration in a case where the solid-state imaging device is constituted by stacking two semiconductor substrates.

FIG. 3A illustrates a conceptual diagram of constituting the solid-state imaging device 1 by stacking two semiconductor substrates 11, which are an upper substrate 11A and a lower substrate 11C.

At least the pixel circuit 41 including a photodiode 121 is formed on the upper substrate 11A. At least the data storage unit 52 that stores the time code and the time code transfer unit 23 are formed on the lower substrate 11C. The upper substrate 11A and the lower substrate 11C are bonded by, for example, metal bonding such as Cu—Cu.

FIG. 3B illustrates a circuit configuration example formed on each of the upper substrate 11A and the lower substrate 11C.

The pixel circuit 41 is disposed on the upper substrate 11A. On the lower substrate 11C, the time code transfer unit 23, the pixel drive circuit 24, the DAC 25, the time code generation unit 26, the vertical drive circuit 27, the output unit 28, the timing generation circuit 29, and a voltage generation unit 30 are formed.

A pixel signal connection unit 24a disposed on the upper substrate 11A is connected to the pixel drive circuit 24 disposed on the lower substrate 11C. A DAC signal connection unit 25a disposed on the upper substrate 11A is connected to the DAC 25 disposed on the lower substrate 11C. A voltage connection unit 30a disposed on the upper substrate 11A is connected to the voltage generation unit 30 disposed on the lower substrate 11C.

### Second Example of Plural-Substrate Configuration

FIG. 4A is a conceptual diagram of constituting the solid-state imaging device by stacking three semiconductor substrates. FIG. 4B is diagram illustrating a schematic configuration in a case where the solid-state imaging device is constituted by stacking three semiconductor substrates.

FIG. 4A illustrates a conceptual diagram of constituting the solid-state imaging device 1 by stacking three semiconductor substrates 11, which are the upper substrate 11A, an intermediate substrate 11B, and the lower substrate 11C.

On the upper substrate 11A, the pixel circuit 41 including the photodiode 121 and at least a part of a circuit of the comparison circuit 51 are formed. On the lower substrate 11C, at least a part of the data storage unit 52 that stores the time code, and the time code transfer unit 23 are formed. On the intermediate substrate 11B, the rest of the circuit of the comparison circuit 51 not disposed on the upper substrate 11A and the rest of the circuit of the data storage unit 52 not disposed on the lower substrate 11C are formed. The upper substrate 11A and the intermediate substrate 11B, and the intermediate substrate 11B and the lower substrate 11C are bonded by, for example, metal bonding such as Cu—Cu.

FIG. 4B illustrates a circuit configuration example formed on each of the upper substrate 11A, the intermediate substrate 11B, and the lower substrate 11C.

In the example in FIG. 4B, a circuit disposed on the upper substrate 11A is the same as the circuit of the upper substrate 11A illustrated in FIG. 3B. The DAC 25 is disposed on the intermediate substrate 11B. The time code transfer unit 23 is disposed on the lower substrate 11C.

A connection unit 28a disposed on the intermediate substrate 11B is connected to the output unit 28 disposed on the lower substrate 11C.

### First Embodiment

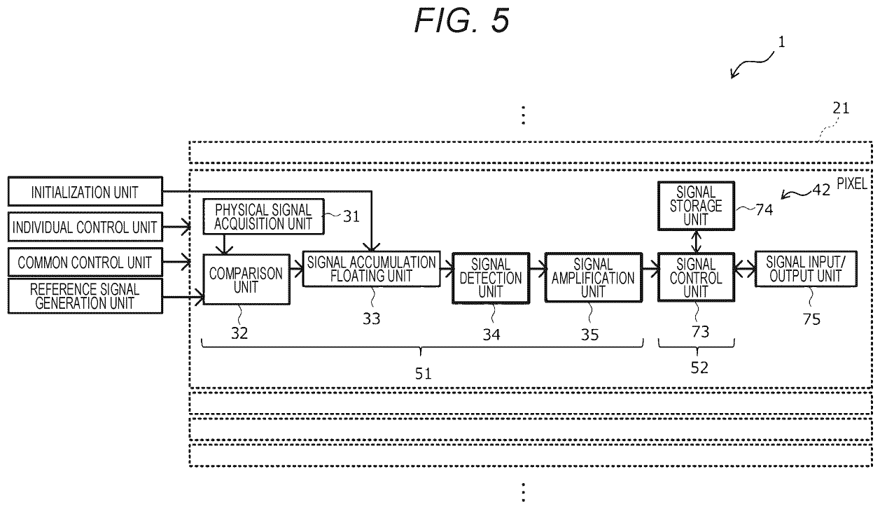

FIG. 5 is a circuit diagram illustrating a configuration example of the solid-state imaging device 1 according to a first embodiment. Note that the first embodiment is a case where the solid-state imaging device is constituted by stacking three semiconductor substrates illustrated in FIGS. 4A and 4B.

The solid-state imaging device 1 includes a physical signal acquisition unit 31, a comparison unit 32, a signal accumulation floating unit 33, a signal detection unit 34, a signal amplification unit 35, a signal control unit 73, a signal storage unit 74, and a signal input/output unit 75.

The physical signal acquisition unit 31 acquires a physical signal. The physical signal acquisition unit 31 corresponds to, for example, the photodiode 121. In this case, the physical signal is a pixel signal.

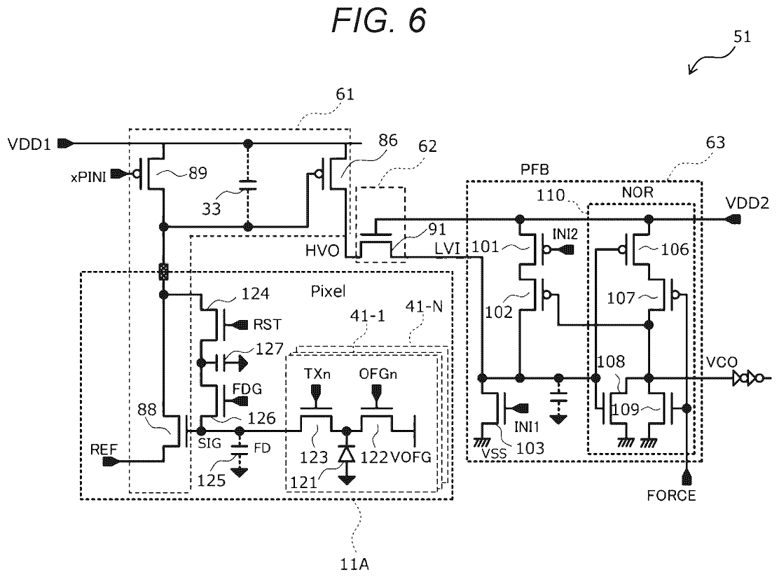

The comparison unit 32 compares the physical signal acquired by the physical signal acquisition unit 31 with the reference signal REF. The comparison unit 32 corresponds to, for example, a transistor 88 to be described later with reference to FIG. 6.

The signal accumulation floating unit 33 is electrically connected to one end of the comparison unit 32. The signal accumulation floating unit 33 accumulates a signal (charge) in an electrically floating state.

The signal detection unit 34 detects the physical signal accumulated in the signal accumulation floating unit 33. The signal detection unit 34 corresponds to a transistor 86 of the differential input circuit 61 to be described later with reference to FIG. 6.

The signal amplification unit 35 amplifies the detection result of the signal detection unit 34. The signal amplification unit 35 corresponds to the positive feedback circuit 63 to be described later with reference to FIG. 6.

In the writing operation, the signal control unit 73 performs control to store the time code output from the signal input/output unit 75 in the signal storage unit 74 on the basis of the comparison result of the comparison unit 32. Furthermore, in the reading operation, the signal control unit 73 outputs the time code of the time when the comparison result is inverted, which is stored in the signal storage unit 74, to the signal input/output unit 75. The signal control unit 73 corresponds to the latch control circuit 71 illustrated in FIG. 2.

The signal storage unit 74 stores the time code. The signal storage unit 74 corresponds to the latch storage unit 72 illustrated in FIG. 2.

The signal input/output unit 75 inputs/outputs (transfers) time data. The signal input/output unit 75 corresponds to the time code transfer unit 23 illustrated in FIG. 2.

FIG. 5 illustrates a plurality of the pixels. At least two or more of the pixels 21 operate in parallel.

Furthermore, an initialization unit, an individual control unit, a common control unit, and a reference signal generation unit are connected to each pixel 21.

FIG. 6 is a circuit diagram illustrating an example of a configuration of the comparison circuit 51 according to the first embodiment. FIG. 6 is a circuit diagram illustrating detailed configurations of the differential input circuit 61, the voltage conversion circuit 62, and the positive feedback circuit 63 constituting the comparison circuit 51. Note that FIG. 6 also illustrates the pixel circuit 41.

The differential input circuit 61 compares the pixel signal SIG output from the pixel circuit 41 in the pixel 21 with the reference signal REF output from the DAC 25, and outputs a predetermined signal (current) when the pixel signal SIG is higher than the reference signal REF.

The differential input circuit 61 includes the transistor 88 constituting the comparison unit 32, a transistor 89 that initializes the signal accumulation floating unit 33, and the transistor 86 that outputs an output signal HVO of the differential input circuit 61.

The transistor 88 includes a negative channel metal-oxide-semiconductor (NMOS) transistor, and the transistors 86 and 89 include positive channel metal-oxide-semiconductor (PMOS) transistors.

The reference signal REF output from the DAC 25 is input to the source of the transistor 88, and the pixel signal SIG output from the pixel circuit 41 in the pixel 21 is input to the gate of the transistor 88. The drain of the transistor 88 is electrically connected to the signal accumulation floating unit 33. When the gate-source voltage exceeds the threshold voltage, the transistor 88 is turned on, and the charge of the drain of the transistor 88 is extracted to the source of the transistor 88.

The source of the transistor 89 is connected to a power supply voltage VDD1. The drain of the transistor 88 is connected to the signal accumulation floating unit 33, the drains of the transistor 88 and a transistor 124, and the gate of the transistor 86. An initialization signal xPINI is supplied to the gate of the transistor 89.

As the charge is extracted from the drain of the transistor 88 to the source of the transistor 88, the input voltage to the gate of the transistor 86 decreases, and the transistor 86 is turned on. That is, the signal detection unit 34 operates.

The voltage conversion circuit 62 includes, for example, an NMOS transistor 91. The drain of the transistor 91 is connected to the drain of the transistor 86 of the differential input circuit 61, the source of the transistor 91 is connected to a predetermined connection point in the positive feedback circuit 63, and the gate of the transistor 91 is connected to a power supply voltage VDD2.

The transistors 86, 88, and 89 constituting the differential input circuit 61 are circuits operating at a high voltage up to the power supply voltage VDD1, and the positive feedback circuit 63 is a circuit operating at the power supply voltage VDD2 lower than the power supply voltage VDD1. The voltage conversion circuit 62 converts the output signal HVO input from the differential input circuit 61 into a low-voltage signal (converted signal) LVI with which the positive feedback circuit 63 can operate, and supplies the signal to the positive feedback circuit 63.

The positive feedback circuit 63 outputs a comparison result signal that is inverted when the pixel signal SIG is higher than the reference signal REF, on the basis of the converted signal LVI obtained by converting the output signal HVO from the differential input circuit 61 into a signal corresponding to the power supply voltage VDD2. Furthermore, the positive feedback circuit 63 increases the transition speed of the time when the output signal VCO output as the comparison result signal is inverted.

The positive feedback circuit 63 includes three transistors 101 to 103 and a NOR circuit 110. The NOR circuit 110 includes four transistors 106 to 109. Here, the transistors 101, 102, 106, and 107 are constituted of PMOS transistors, and the transistors 103, 108, and 109 are constituted of NMOS transistors.

The source of the transistor 91, which is an output terminal of the voltage conversion circuit 62, is connected to the drains of the transistors 102 and 103 and the gates of the transistors 106 and 108. The sources of the transistors 101 and 106 are connected to the power supply voltage VDD2, the drain of the transistor 101 is connected to the source of the transistor 102, and the gate of the transistor 102 is connected to the drains of the transistors 107, 108, and 109 which are also output terminals of the positive feedback circuit 63. The sources of the transistors 103, 108, and 109 are connected to a predetermined voltage VSS. Initialization signals INI2 and INI1 are supplied to the gates of the transistors 101 and 103, respectively. A FORCE signal is supplied to the gates of the transistors 107 and 109.

The transistors 106 to 109 constitute the NOR circuit 110, and a connection point between the drains of the transistors 107 to 109 is an output terminal at which the comparison circuit 51 outputs the output signal VCO.

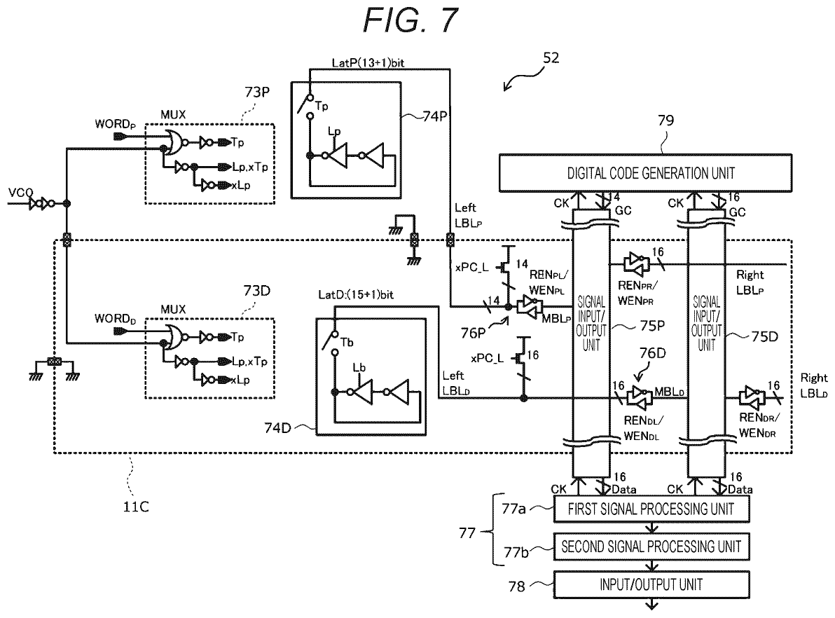

Note that, as illustrated in FIG. 6, a plurality of pixel circuits 41-1 to 41-N is connected to one transistor 88. That is, the transistor 88 is shared by the plurality of photodiodes 121. Similarly, signal input/output units 75P and 75D illustrated in FIG. 7 are shared by the plurality of photodiodes 121.

### Detailed Configuration Example of Pixel Circuit

A detailed configuration of the pixel circuit 41 will be described with reference to FIG. 6.

The pixel circuit 41 includes the photodiode (PD) 121 as a photoelectric conversion element, a discharge transistor 122, a transfer transistor 123, a reset transistor 124, a floating diffusion layer (FD) 125, a gain control transistor 126, and a capacitor 127.

The discharge transistor 122 is used in a case where the exposure period is adjusted. Specifically, if the discharge transistor 122 is turned on when it is desired to start the exposure period at an optional timing, charge accumulated in the photodiode 121 until that time point are discharged, and thus, the exposure period is started after the discharge transistor 122 is turned off.

The transfer transistor 123 transfers the charge generated by the photodiode 121 to the FD 125. The reset transistor 124 and the transistor 127 resets the charge held in the FD 125. The FD 125 is connected to the gate of the transistor 88 of the differential input circuit 61. With this arrangement, the transistor 88 of the differential input circuit 61 also functions as an amplification transistor of the pixel circuit 41.

The source of the reset transistor 124 is connected to the source of the gain control transistor 126 and the capacitor 127, and the drain of the reset transistor 124 is connected to the drains of the transistors 88 and 89. The reset voltage is set to a reset voltage obtained by setting the gate of the transistor 89 controlled by the initialization signal xPINI to a Low voltage to make the power supply voltage VDD1 conductive.

The gain control transistor (switching unit) 126 is connected between the transfer transistor 123 and the reset transistor 124. A drive signal FDG is input to the gate of the gain control transistor 126. When the drive signal FDG turns into the active state, the gain control gate of the gain control transistor 126 turns into the conductive state, and the FD 125 is electrically connected to the capacitor (additional capacitance unit) 127 that adds capacitance. With this arrangement, the sensitivity of signal detection can be controlled.

FIG. 7 is a circuit diagram illustrating an example of a configuration of the data storage unit 52 according to the first embodiment.

The data storage unit 52 includes signal control units 73P and 73D, signal storage units 74P and 74D, and signal input/output units 75P and 75D. Note that FIG. 7 also illustrates the bidirectional buffer circuits 76P and 76D, a signal processing unit 77, and an input/output unit 78.

The signal control units 73P and 73D correspond to the latch control circuit 71 illustrated in FIG. 2. The signal storage units 74P and 74D correspond to the latch storage unit 72 illustrated in FIG. 2. The signal input/output units 75P and 75D correspond to the time code transfer unit 23 illustrated in FIG. 2. The signal processing unit 77 and the input/output unit 78 correspond to the output unit 28 illustrated in FIG. 4B.

The data storage unit 52 illustrated in FIG. 5 is constituted by being divided into the signal control unit 73P, the signal storage unit 74P, and the signal input/output unit 75P that acquire a reset level in a P-phase period, and the signal control unit 73D, the signal storage unit 74D, and the signal input/output unit 75D that acquire a data (pixel signal) level in a D-phase period (data (pixel signal) acquisition period).

The signal input/output units 75P and 75D are supplied with the digital time codes from a digital code generation unit 79 corresponding to the time code generation unit 26 illustrated in FIG. 1, and the signals output from the signal storage units 74P and 74D to the signal input/output units 75P and 75D are output via the signal processing unit 77 and the input/output unit 78.

The signal input/output units 75P and 75D are, for example, repeaters. Furthermore, in the signal input/output units 75P and 75D, for example, each of N pieces of shift registers includes a plurality of D-flip-flops (D-F/Fs). Note that the signal input/output units 75P and 75D may include a tri-state inverter instead of the flip-flop.

Each of the bidirectional buffer circuits 76P and 76D is connected between corresponding ones of the signal storage units 74P and 74D and the signal input/output units 75P and 75D. The bidirectional buffer circuits 76P and 76D switch the writing operation and the reading operation of the time code for the signal storage units 74P and 74D on the basis of the write control signal WR and the read control signal RD.

The signal processing unit 77 includes a first signal processing unit 77a and a second signal processing unit 77b.

The first signal processing unit (CDS unit) 77a performs correlated double sampling processing of obtaining a difference between the reset level in the P-phase period and the data level in the D-phase period.

The second signal processing unit (DSP unit) 77b performs digital signal processing on the signal output from the first signal processing unit 77a. The digital signal processing includes, for example, image processing such as adjustment of white balance of an image, color interpolation (color correction), and compression, and in addition thereto, correction of a defective pixel having an abnormal digital output.

The input/output unit 78 outputs the signal processed by the second signal processing unit 77b.

Note that the first embodiment illustrated in FIGS. 6 and 7 illustrates a case where three semiconductor substrates 11 are stacked as illustrated in FIGS. 4A and 4B. On the upper substrate 11A, for example, the pixel circuit 41, the reset transistor 124, the FD 125, the gain control transistor 126, the transistor 88, and the like are disposed. On the intermediate substrate 11B, for example, the transistors 86 and 89 among the differential input circuit 61, the voltage conversion circuit 62, the signal control unit 73P and the signal storage unit 74P among the data storage unit 52, and the like are disposed. On the lower substrate 11C, for example, the signal control unit 73D and the signal storage unit 74D among the data storage unit 52, the signal input/output units 75P and 75D, and the like are disposed.

### Pixel Unit Timing Chart

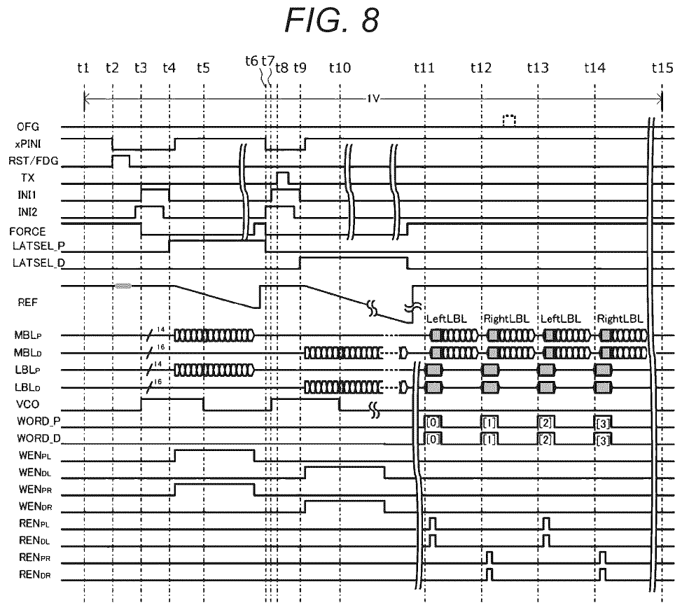

FIG. 8 is a timing chart illustrating an example of operation of the comparison circuit 51 and the data storage unit 52 according to the first embodiment.

Time t1 is a start time of 1 V (one vertical scanning period).

First, at time t2, the reset transistor 124 and the gain control transistor 126 are turned on to cause the charge of the FD 125 to be reset. Furthermore, at time t2, the initialization signal xPINI supplied to the gate of the transistor 89 is set to Low, and the signal accumulation floating unit 33 is set to the initial state.

At time t3, because the initialization signal INI1 supplied to the gate of the transistor 103 is set to Hi and the initialization signal INI2 is also set to Hi, the positive feedback circuit 63 is set to the initial state. Furthermore, the FORCE signal input to the gates of the transistors 107 and 109 is set to Low. At this time point, because the reference signal REF is larger than the pixel signal SIG, the output signal VCO is Hi. Thereafter, the initialization signals INI1 and INI2 are returned to Low.

At time t4, a LATSEL_P signal is set to Hi to cause the signal storage unit 74P to be enabled. Thereafter, the initialization signal xPINI is returned to Hi, the comparison circuit 51 turns into the operable state, and comparison between the reference signal REF and the pixel signal SIG (sweep of the reference signal REF) is started. Along with the sweeping of the reference signal REF, the signal input/output unit 75P transfers the time code. The time code is desirably a gray code resistant to data destruction due to a timing shift.

At time t5 at which the difference (gate-source voltage) between the voltage of the reference signal REF and the voltage of the pixel signal SIG becomes larger than the threshold voltage of the transistor 88, the output signal VCO is inverted (transitioned to Low). As described above, the inversion of the output signal VCO is speeded up by the positive feedback circuit 63. Furthermore, the signal storage unit 74P of the data storage unit 52 stores time data (N-bit DATA [1] to DATA [N]) at the time point at which the output signal VCO is inverted.

Thereafter, the FORCE signal is set to Hi, the positive feedback circuit 63 of the pixel circuit 41 that has not been inverted is forcibly inverted, and a code having a final value is acquired. Furthermore, the reference signal REF is raised to a predetermined voltage. Furthermore, by causing the LATSEL_P signal to be returned to Low, writing to the signal storage unit 74P is disabled.

Subsequently, the circuit is initialized again for acquisition of the D-phase level (signal level).

At time t6, the initialization signal xPINI supplied to the gate of the transistor 89 is set to Low, and the signal accumulation floating unit 33 is set to the initial state.

At time t7, because the initialization signal INI1 is set to Hi and the initialization signal INI2 is also set to Hi, the positive feedback circuit 63 is set to the initial state again.

At time t8, the transfer transistor 123 of the pixel circuit 41 is turned on by a transfer signal TX at Hi, and the charge generated by the photodiode 121 is transferred to the FD 125.

Thereafter, the initialization signals INI1 and INI2 are returned to Low.

At time t9, a LATSEL_D signal is set to Hi to cause the signal storage unit 74D to be enabled. Thereafter, the initialization signal xPINI is returned to Hi, the comparison circuit 51 turns into the operable state, and comparison between the reference signal REF and the pixel signal SIG (sweep of the reference signal REF) is started. Along with the sweeping of the reference signal REF, the signal input/output unit 75D transfers the time code. The time code is desirably a gray code resistant to data destruction due to a timing shift.

At time t10 at which the difference (gate-source voltage) between the voltage of the reference signal REF and the voltage of the pixel signal SIG becomes larger than the threshold voltage of the transistor 88, the output signal VCO is inverted (transitioned to Low). The inversion of the output signal VCO is speeded up by the positive feedback circuit 63. Furthermore, the signal storage unit 74D of the data storage unit 52 stores time data (N-bit DATA [1] to DATA [N]) at the time point at which the output signal VCO is inverted.

Thereafter, the FORCE signal is set to Hi, the positive feedback circuit 63 of the pixel circuit 41 that has not been inverted is forcibly inverted, and a code having a final value is acquired. Furthermore, by causing the LATSEL_D signal to be returned to Low, writing to the signal storage unit 74D is disabled. Furthermore, the reference signal REF is raised to a predetermined voltage.

At times t11, t12, t13, and t14, a WORD_P signal and WARD_D for controlling the read timing become Hi, and an N-bit latch signal Col [n] (n=1 to N) (not illustrated) is output from the latch control circuit 71 of the data storage unit 52. The data acquired here is the P-phase data of the reset level and the D-phase data of the signal level of the time when the CDS processing is performed. Time t15 is the same state as time t1 described above, and is the next drive of 1 V (one vertical scanning period).

According to the above driving of the pixel 21, first, the P-phase data (reset level) is acquired, next, the D-phase data (signal level) is acquired, and next, the P-phase data and the D-phase data are simultaneously read out.

Note that all the operations are performed in pixel parallel, and when the data acquisition (A/D conversion) of each of the pixels 21 is completed, data is output to the outside of the pixel array unit 22 through the signal input/output units 75P and 75D. Because the signal input/output units 75P and 75D are provided for every latch group (each of the P phase and D phase), reading can be performed simultaneously.

According to the above operation, in a case of N=1 in the pixel 41-N in FIG. 6, because one A/D converter is provided for each pixel, each pixel 21 of the pixel array unit 22 of the solid-state imaging device 1 can perform a global shutter operation of simultaneously resetting all pixels and simultaneously exposing all pixels. Because all the pixels can be exposed and read simultaneously, it is unnecessary to provide a holding unit usually provided in the pixel and configured to hold the charge until the charge is read. Furthermore, in the configuration of the pixel 21, a select transistor or the like for selecting a pixel that outputs the pixel signal SIG, which has been necessary in the column parallel reading type solid-state imaging device, is also unnecessary.

In the driving of the pixel 21 described with reference to FIG. 8, the discharge transistor 122 is always controlled to be turned off. However, as indicated by a broken line in FIG. 8, it is also possible to set an optional exposure period by setting a discharge signal OFG to Hi, temporarily turning on the discharge transistor 122, and then turning the discharge transistor off at a desired time.

As described above, according to the first embodiment, the transistor 88 as the comparison unit 32 compares the pixel signal SIG as a physical signal input to the gate with the reference signal REF supplied to the source. When the gate-source voltage of the transistor 88 becomes larger than the threshold of the transistor 88, the transistor 88 is turned on, and the charge on the drain side of the transistor 88 is extracted to the source side. As the charge is extracted, the input voltage of the gate of the transistor 86 as the signal detection unit 34 decreases. With this arrangement, the transistor 86 as the signal detection unit 34 is turned on.

Furthermore, in the first embodiment, two signal input/output units 75P and 75D are provided. With this arrangement, the reset level in the P-phase period and the data level in the D-phase period can be read at the same time, and the speed can be increased. Furthermore, the P-phase and the D-phase can be individually controlled, and the wiring and the circuit can be simplified.

Note that, for example, the signal input/output units 75P and 75D may be disposed separately on the intermediate substrate 11B and the lower substrate 11C as different substrates. However, in a case where the signal input/output units 75P and 75D are disposed on the same substrate, the efficiency can be improved.

Furthermore, in the first embodiment, the signal control unit 73P and the signal storage unit 74P, and the signal control unit 73D and the signal storage unit 74D are disposed on the intermediate substrate 11B and the lower substrate 11C, which are different substrates from each other. However, the signal control unit 73P and the signal storage unit 74P, and the signal control unit 73D and the signal storage unit 74D may be disposed on the same substrate.

### First Comparative Example

As a first comparative example, a case where the differential input circuit 61 includes a differential pair transistor will be described.

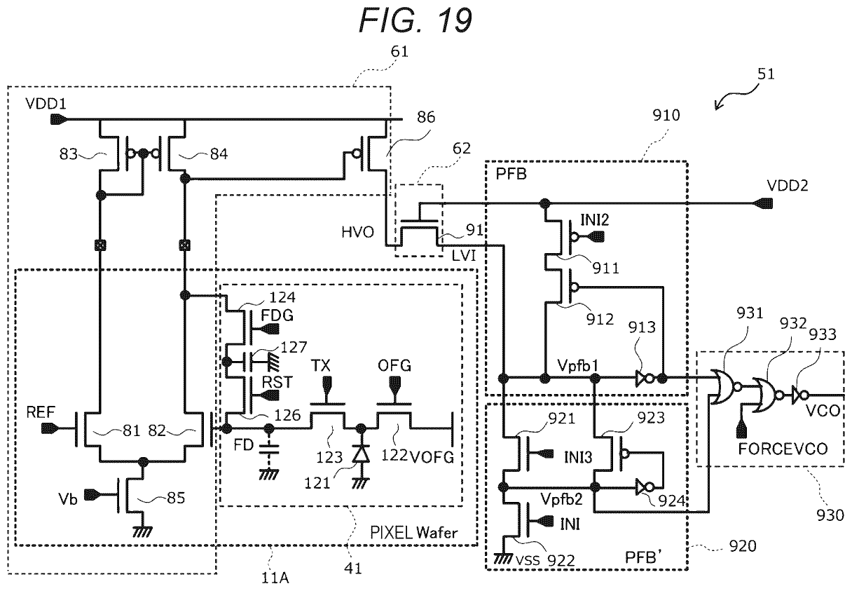

In the first comparative example, the pixel signal SIG and the reference signal REF are supplied to the gates of the differential pair transistors (for example, transistors 81 and 82 illustrated in FIG. 19). In this case, in order to operate the differential input circuit 61, a current source (for example, a transistor 85 illustrated in FIG. 19) through which a direct current flows is required.

On the other hand, in the first embodiment, a current source is not provided, and it is not necessary to cause a constant current to flow. With this arrangement, the power consumption can be reduced.

### Second Comparative Example

As a second comparative example, a case where the ADC 42 is disposed outside the pixel array unit 22 will be described.

In the second comparative example, AD conversion is performed for every column (pixel column) having the plurality of pixels 21. A vertical signal line connecting the plurality of pixels and the comparison circuit (column processing unit) is provided for every pixel column. The vertical signal line becomes longer as the number of pixels in the pixel array unit 22 increases. When the charge is extracted from the drain to the source of the transistor 88, streaking possibly occurs due to the influence of parasitic capacitance corresponding to the distance of the vertical signal line.

On the other hand, in the first embodiment, the ADC 42 is disposed in the pixel array unit 22. In this case, because the AD conversion is performed for every pixel 21 and the transistor 86 as the signal detection unit 34 is disposed in the pixel array unit 22, the wiring through which the charge is extracted is disposed in the pixel 21. The distance of the wiring from which the charge is drawn is, for example, a distance from the drain of the transistor 88 to the gate of the transistor 86. As a result, the wiring distance to the signal detection unit 34 can be shortened, and the occurrence of streaking due to the parasitic capacitance can be suppressed.

### First Modification of First Embodiment

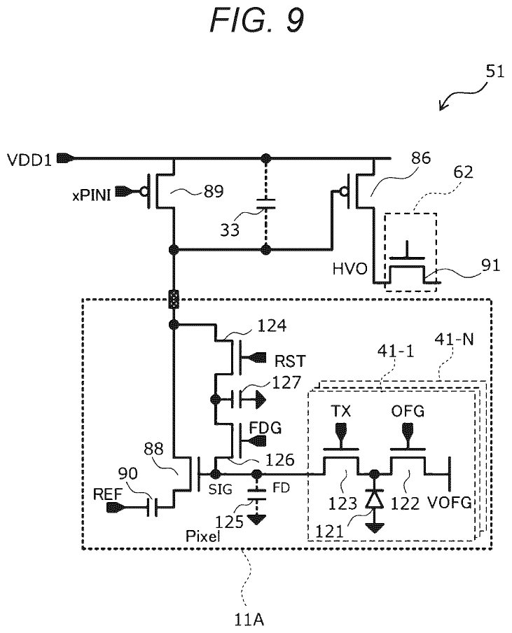

FIG. 9 is a circuit diagram showing an example of a configuration of the comparison circuit 51 according to a first modification of the first embodiment. The first modification of the first embodiment is different from the first embodiment in that a capacitor 90 is provided.

The solid-state imaging device 1 further includes the capacitor 90. The capacitor 90 is connected between the DAC 25 and the source of the transistor 88. One end of the capacitor 90 is connected to the DAC 25. The other end of the capacitor 90 is connected to the source of the transistor 88.

Other configurations of the solid-state imaging device 1 in the first modification of the first embodiment may be similar to the corresponding configurations of the first embodiment. Furthermore, the operations of the comparison circuit 51 and the data storage unit 52 according to the first modification of the first embodiment are substantially the same as those of the first modification.

Assuming that the capacitance of the source of the transistor 88 is Cc and the remaining parasitic capacitance is Cs, the capacitance Ctotal visible from the outside (DAC 25) is expressed by Expression 1.

Ctotal=Cc×Cs/(Cc+Cs) (Expression 1)

Therefore, the capacitance Ctotal appears small from the outside by voltage division. With this arrangement, the influence of kickback of the capacity fluctuation can be reduced. For example, in a case where there is a pixel that has not yet been inverted around a previously inverted pixel, there is a possibility that the voltage of the reference signal REF is affected by the distortion due to the fluctuation in the load capacitance, and the originally intended AD conversion cannot be correctly performed, and the input/output characteristics are distorted. This phenomenon is generally called streaking. By providing the capacitor 90, the streaking can be reduced.

Furthermore, by providing the capacitor 90, the charge in the signal accumulation floating unit 33 does not directly flow into the ADC 25, and the movement of the charge is restricted to achieve low power consumption.

As in the first modification of the first embodiment, the capacitor 90 may be provided. Also in this case, the similar effects to those of the first embodiment can be obtained.

### Second Modification of First Embodiment

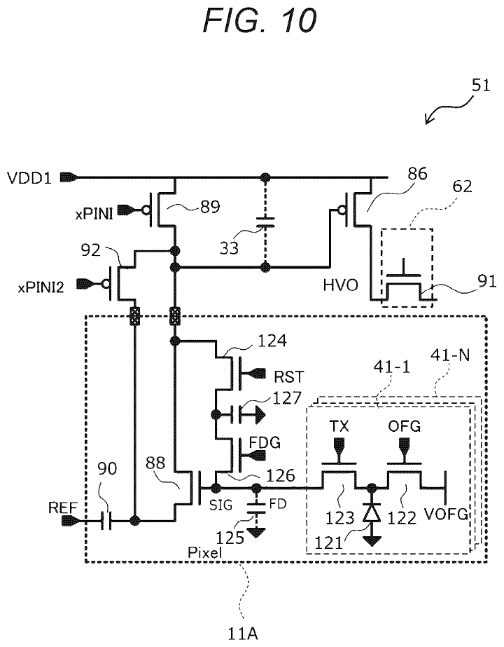

FIG. 10 is a circuit diagram showing an example of a configuration of the comparison circuit 51 according to a second modification of the first embodiment. The second modification of the first embodiment is different from the first modification of the first embodiment in that a transistor 92 as a connection unit is provided.

In a case where the capacitor 90 remains connected to the source of the transistor 88 as in the first embodiment, for example, there is a possibility that, after the transistor 88 is turned on once, the voltage of the source of the transistor 88 does not immediately return to the initial state due to the capacitor 90. At the time of initialization, the charge at the node is discharged with a resistance of a time constant at the time of the transistor 88 being turned off. Because the transistor 88 is in a high resistance state, it takes a settling time for initialization. This is because it is necessary to wait until the voltage of the source returns before the reference signal REF is supplied to the source of the transistor 88 again.

Therefore, the solid-state imaging device 1 further includes the transistor 92 as the connection unit (initialization unit). The transistor 92 is constituted of, for example, a PMOS transistor.

The transistor 92 is connected between the drain of the transistor 88 and the source of the transistor 88. The drain of the transistor 92 is connected to the source of the transistor 88 and the capacitor 90. The source of the transistor is connected to the drain of the transistor 88, the drain of the transistor 89, and the gate of the transistor 86. An initialization signal xPINI2 is supplied to the gate of the transistor 92.

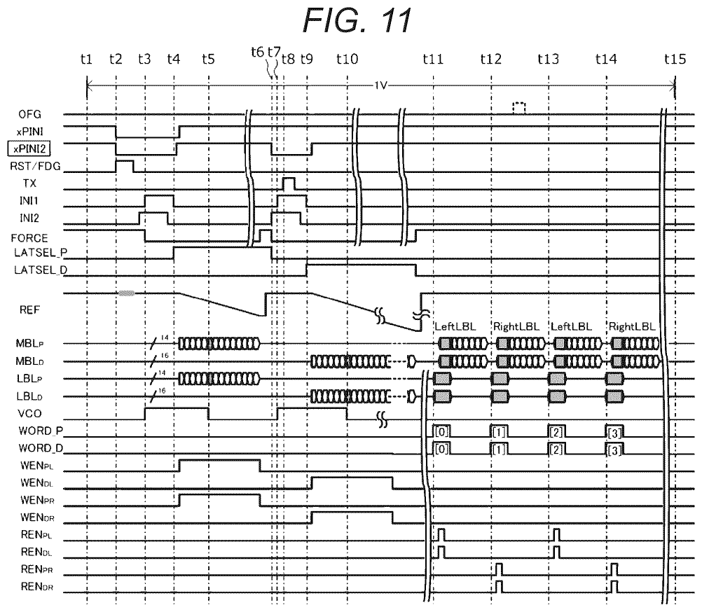

The transistor 92 as the connection unit (initialization unit) is turned on to electrically connect the source of the transistor 88 and the drain of the transistor 88 at a predetermined timing. Note that the predetermined timing is, for example, a timing at which the initialization signal xPINI2 illustrated in FIG. 11 described later becomes Low. That is, the transistor 92 forcibly initializes the voltage of the source of the transistor 88. With this arrangement, the charge moved to the source of the transistor 88 when the transistor 88 is turned on can be forcibly returned to the drain of the transistor 88. As a result, the settling time of initialization can be shortened.

Furthermore, the initialization is performed by using the initialization signal xPINI2 before the D-phase is started, but by setting the reference signal REF to the same voltage as that at the start of the P-phase, the total amount of charge of the signal accumulation floating unit 33 and the source of the transistor 88 returns to the original value and becomes the same. Therefore, the initialization signal xPINI does not need to be controlled again in the D-phase period as in the P-phase period. Therefore, the influence of kT/C noise that occurs in a case where the initialization signal xPINI is controlled again is reduced. As a result, deterioration in signal quality, that is, deterioration in image quality can be suppressed.

Other configurations of the solid-state imaging device 1 in the first modification of the first embodiment may be similar to the corresponding configurations of the first embodiment.

FIG. 11 is a timing chart illustrating an example of operation of the comparison circuit 51 and the data storage unit 52 according to the second modification of the first embodiment.

Note that operations other than the initialization signal xPINI2 supplied to the gate of the transistor 92 and the initialization signal xPINI before the D-phase is started are similar to those in FIG. 8 described with reference to the first embodiment.

At time t2, the initialization signal xPINI2 supplied to the gate of the transistor 92 is set to Low, and the source of the transistor 88 is set to the initial state. With this arrangement, the voltage of the source of the transistor 88 is forcibly initialized. After time t4, the initialization signal xPINI2 is returned to Hi before the sweep of the reference signal REF.

At time t6, the initialization signal xPINI2 supplied to the gate of the transistor 92 is set to Low, and the source of the transistor 88 is set to the initial state. With this arrangement, the voltage of the source of the transistor 88 is forcibly initialized. After time t9, the initialization signal xPINI2 is returned to Hi before the sweep of the reference signal REF.

As in the second modification of the first embodiment, the transistor 92 may be provided. Also in this case, the similar effects to those of the first embodiment can be obtained.

### Third Modification of First Embodiment

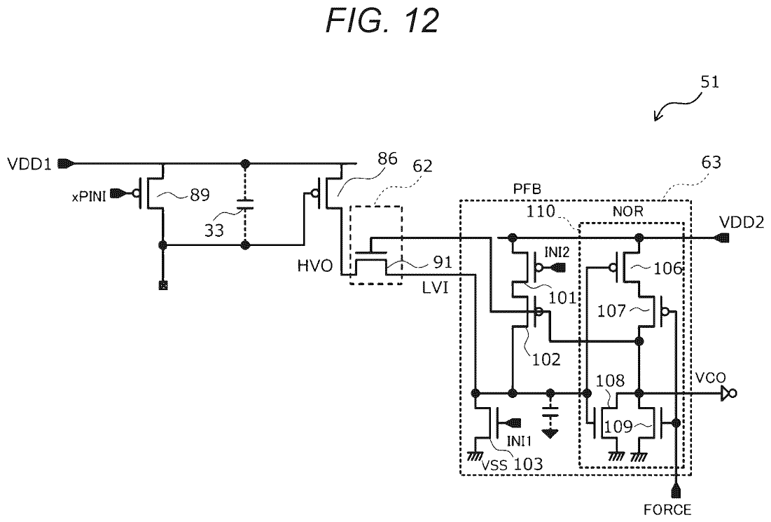

FIG. 12 is a circuit diagram showing an example of a configuration of the comparison circuit 51 according to a third modification of the first embodiment. The third modification of the first embodiment is different from the first embodiment in that the output of the NOR circuit 110 is input to the gate of the transistor 91 of the voltage conversion circuit 62 instead of the power supply voltage VDD2.

The gate of the transistor 91 is connected to the output terminal of the NOR circuit 110. The output signal VCO which is an output of the NOR circuit 110 is supplied to the gate of the transistor 91. With this arrangement, in a case where the output signal VCO is inverted, the transistor 91 is turned off, and the current from the differential input circuit 61 can be cut off. Furthermore, a rush current from the power supply voltage VDD2 to the power supply voltage VDD1 can be suppressed in a case where the power supply voltage VDD2 rises earlier than the power supply voltage VDD1 by powering up.

As in the third modification of the first embodiment, the connection of the gate of the transistor 91 of the voltage conversion circuit 62 may be changed. Also in this case, the similar effects to those of the first embodiment can be obtained. Furthermore, the third modification of the first embodiment may be combined with the first modification or the second modification of the first embodiment.

### Fourth Modification of First Embodiment

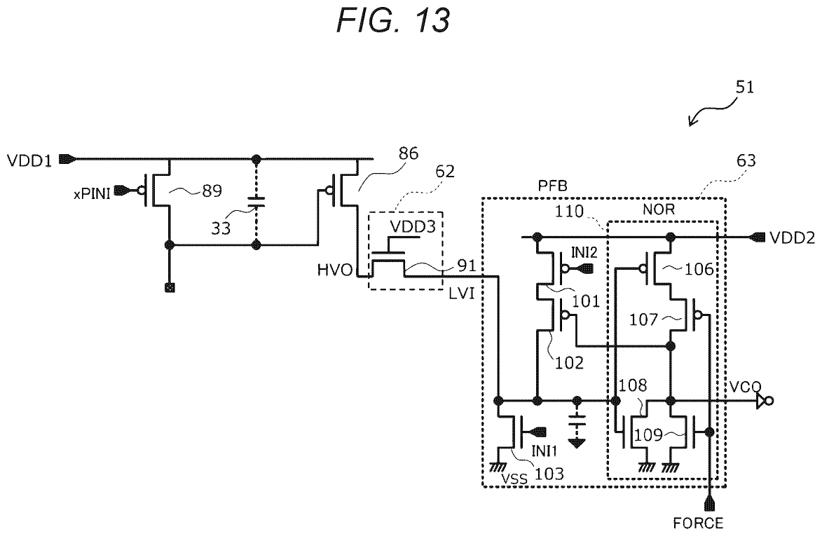

FIG. 13 is a circuit diagram showing an example of a configuration of the comparison circuit 51 according to a fourth modification of the first embodiment. The fourth modification of the first embodiment is different from the first embodiment in that another power supply voltage is input to the gate of the transistor 91 of the voltage conversion circuit 62.

A power supply voltage VDD3 (bias voltage VBIAS) is supplied to the gate of the transistor 91. The bias voltage VBIAS may be any voltage as long as the voltage is converted into a voltage that does not destroy each transistor of the positive feedback circuit 63 operating at a constant voltage.

As in the fourth modification of the first embodiment, the connection of the gate of the transistor 91 of the voltage conversion circuit 62 may be changed. Also in this case, the similar effects to those of the first embodiment can be obtained. Furthermore, the fourth modification of the first embodiment may be combined with the first modification or the second modification of the first embodiment.

### Fifth Modification of First Embodiment

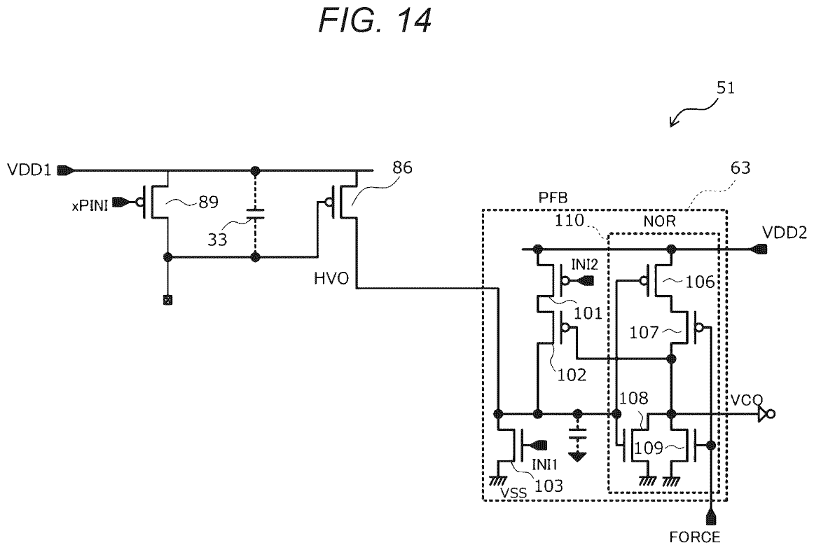

FIG. 14 is a circuit diagram showing an example of a configuration of the comparison circuit 51 according to a fifth modification of the first embodiment. The fifth modification of the first embodiment is different from the first embodiment in that the voltage conversion circuit 62 is not provided.

In a case where the power supply voltage VDD1 and the power supply voltage VDD2 are close to each other, the voltage conversion circuit 62 can be omitted. With this arrangement, the number of necessary transistors can be reduced, and the required area can be reduced.

Note that the power supply voltage VDD1 and the power supply voltage VDD2 are desirably different voltages in consideration of noise influence as nodes. However, the power supply voltage VDD1 and the power supply voltage VDD2 may be the same voltage.

Furthermore, in the configuration illustrated in FIG. 14, in order to make the pixel have the same characteristics as in a case where a high power supply is used, it is necessary to adjust an operation point such as setting a substrate potential (Sub potential) on the pixel side to be largely negative.

As in the fifth modification of the first embodiment, the voltage conversion circuit 62 may not be provided. Also in this case, the similar effects to those of the first embodiment can be obtained. Furthermore, the fifth modification of the first embodiment may be combined with the first modification or the second modification of the first embodiment.

### Sixth Modification of First Embodiment

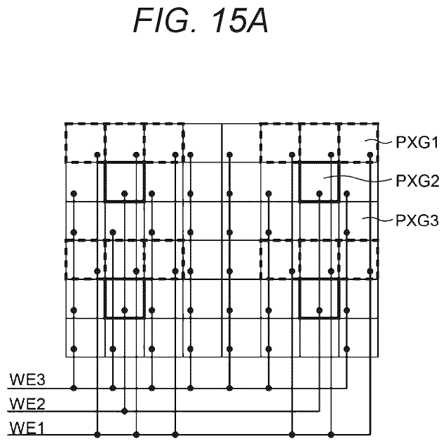

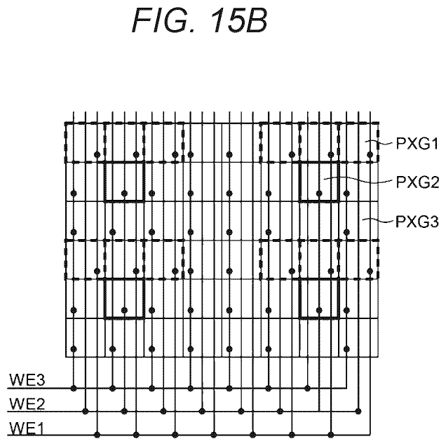

FIG. 15A is a diagram illustrating an example of a pixel group of the pixel array unit 22 according to a sixth modification of the first embodiment. For the sake of simplicity, FIG. 15A illustrates an example in which a first pixel group PXG1 indicated by a broken line, a second pixel group PXG2 indicated by a thick line, and a remaining third pixel group PXG3 indicated by a thin line are provided in the pixel array unit 22 having eight pixels in the horizontal direction and six pixels in the vertical direction. The number of pixels in the pixel array unit 22 and the number of pixel groups provided in the pixel array unit 22 are optional.

The sixth modification of the first embodiment is different from the first embodiment in that a write enable signal is individually provided for every pixel group, and whether or not to update pixel data in the latch storage unit 72 of each pixel is set for every pixel group.

Instead of the FORCE signal, any one of the plurality of enable signals WE1 to WE3 is connected to the gates of the transistors 107 and 109 illustrated in FIG. 6. As will be described later, each pixel in the pixel array unit 22 belongs to any of the plurality of pixel groups, and every pixel group has the write enable signal separately. The positive feedback circuit 63 of each pixel outputs a valid VCO signal when the corresponding write enable signal is in an enable state (for example, a low level). Therefore, in a case where the corresponding write enable signal is not in the enable state, the valid VCO signal is not output from the positive feedback circuit 63, and thus, the time code corresponding to the pixel data is not stored in the latch storage unit 72 in the subsequent stage.

The latch storage unit (storage unit) 72 stores data corresponding to the physical signal (physical quantity) detected by the pixel 21 in each pixel group.

For example, the storage control unit included in the pixel drive circuit 24 or the vertical drive circuit 27 performs control to store data in the latch storage unit 72, and meanwhile, controls whether or not to update the data stored in the latch storage unit 72 for every pixel group. The storage control unit supplies the write enable signal.

The first pixel group PXG1 includes pixel groups including three pixels each at a left end and a right end in the horizontal direction, and these pixel groups are disposed at an interval of two pixels in the vertical direction. The second pixel group PXG2 includes a total of four pixels, and these pixels are disposed at an interval of four pixels in the horizontal direction and at an interval of two pixels in the vertical direction. The third pixel group PXG3 includes pixels other than the first pixel group PXG1 and the second pixel group PXG2 in the pixel array unit 22.

Each pixel in the first pixel group PXG1 is, for example, a pixel for live view (moving image). Because the live view does not require a resolution as high as that of a still image, the first pixel group PXG1 including a part of the pixels obtained by thinning out the pixels for a still image is used.

Each pixel in the second pixel group PXG2 is a pixel for image plane phase difference detection. Each pixel is divided into two, or half of each one pixel is shielded from light, detects a phase difference from an optical signal captured for every divided region, and is used to perform, for example, focus adjustment.

Each pixel in the third pixel group PXG3 is used, for example, for capturing a still image. In the still image, the roughness of the image is easily noticeable. Therefore, it is desirable that the still image has a larger number of pixels than the first pixel group PXG1 and the second pixel group PXG2.

In the present embodiment, as illustrated in FIG. 15A, there are provided a first write enable signal WE1 that permits the pixel signal of each pixel in the first pixel group PXG1 to be stored in the latch storage unit 72, a second write enable signal WE2 that permits the pixel signal of each pixel in the second pixel group PXG2 to be stored in the latch storage unit 72, and a third write enable signal WE3 that permits the pixel signal of each pixel in the third pixel group PXG3 to be stored in the latch storage unit 72. One of the first to third write enable signals WE1 to WE3 is connected to the gates of the transistors 107 and 109 of the positive feedback circuit 63 in FIG. 6 for every pixel. The types of the write enable signals connected to the gates of the transistors 107 and 109 in the pixels belonging to the same pixel group are the same.

When the first write enable signal WE1 becomes the enable state (for example, the high level), the pixel data (to be precise, the time code according to the pixel signal) of all the pixels in the first pixel group PXG1 is stored in the corresponding latch storage unit 72. With this arrangement, the pixel data previously stored in the latch storage unit 72 is updated.

Similarly, when the second write enable signal WE2 becomes the enable state (for example, the high level), the pixel data of all the pixels in the second pixel group PXG2 is stored in the corresponding latch storage unit 72. With this arrangement, the pixel data previously stored in the latch storage unit 72 is updated.

Similarly, when the third write enable signal WE3 becomes the enable state (for example, the high level), the pixel data of all the pixels in the third pixel group PXG3 is stored in the corresponding latch storage unit 72. With this arrangement, the pixel data previously stored in the latch storage unit 72 is updated.

If the pixel data stored in the latch storage unit 72 of each pixel in the first pixel group PXG1, the second pixel group PXG2, and the third pixel group PXG3 can be transferred to the output unit 28 within one frame period, the pixel data in the latch storage unit 72 of each pixel becomes unnecessary in the next frame period, and thus, new pixel data can be stored in the corresponding latch storage unit 72. However, in an area having a large number of pixels like the third pixel group PXG3, there is a possibility that pixel data of all the pixels cannot be transferred to the output unit 28 within one frame period. In particular, in a case where the number of pixels in the pixel array unit 22 is large and the number of pixels in the third pixel group PXG3 is also large, there is a possibility that the transfer of the pixel data from the latch storage unit 72 to the output unit 28 of each pixel in the third pixel group PXG3 is not completed within one frame period. Alternatively, even in a case where the signal reading time of the pixels in the third pixel group PXG3 is long, there is a possibility that the transfer of all the pixel data to the output unit 28 is completed within one frame period.

Therefore, in the present embodiment, the write enable signal is individually provided for every pixel group, and whether or not to update the pixel data in the latch storage unit 72 of each pixel can be set for every pixel group.

In FIG. 15A, control wiring for the first write enable signal WE1, control wiring for the second write enable signal WE2, and control wiring for the third write enable signal WE3 are arranged on the pixel to which the write permission is given, and are not arranged on the pixel to which the write permission is not given as much as possible. A contact indicated by a black circle on each piece of the control wiring in FIG. 15A indicates a pixel controlled by the corresponding write enable signal. Any one of the first to third write enable signals WE1 to WE3 is connected to each pixel in the pixel array unit 22.

By arranging the three pieces of control wiring as illustrated in FIG. 15A, there is an advantage that the arrangement region of the control wiring can be reduced and the aperture ratio of each pixel can be improved, but the arrangement density of the control wiring is increased or decreased depending on the location in the pixel group, and the wiring density does not become uniform. This possibly causes variations in pixel characteristics such as variations in sensitivity.

FIG. 15B is a diagram illustrating a modification of FIG. 15A. FIG. 15B illustrates an example in which three pieces of control wiring are arranged on all the pixels in the pixel array unit 22. In the case of FIG. 15B, three pieces of control wiring are arranged in all the pixels in the pixel array unit 22, the arrangement density of the control wiring becomes uniform, and the aperture ratio of each pixel and the characteristics of the circuit can be equalized.

The order of reading the pixel data of each pixel in each pixel group in the pixel array unit 22 may be the same, or may be different for every pixel group.

As in the sixth modification of the first embodiment, the write enable signal may be individually provided for every pixel group, and whether or not to update the pixel data in the latch storage unit 72 of each pixel may be set for every pixel group. Also in this case, the similar effects to those of the first embodiment can be obtained. Furthermore, the fifth modification of the first embodiment may be combined with the first to fifth modifications of the first embodiment.

### Second Embodiment

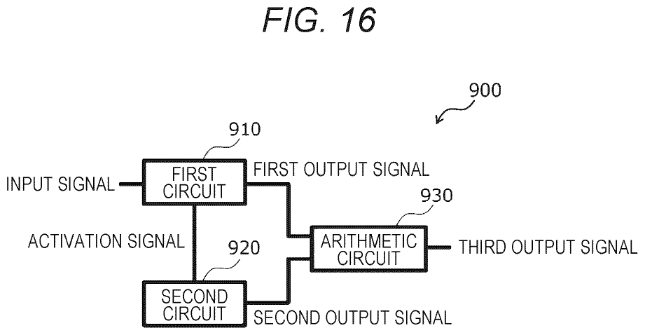

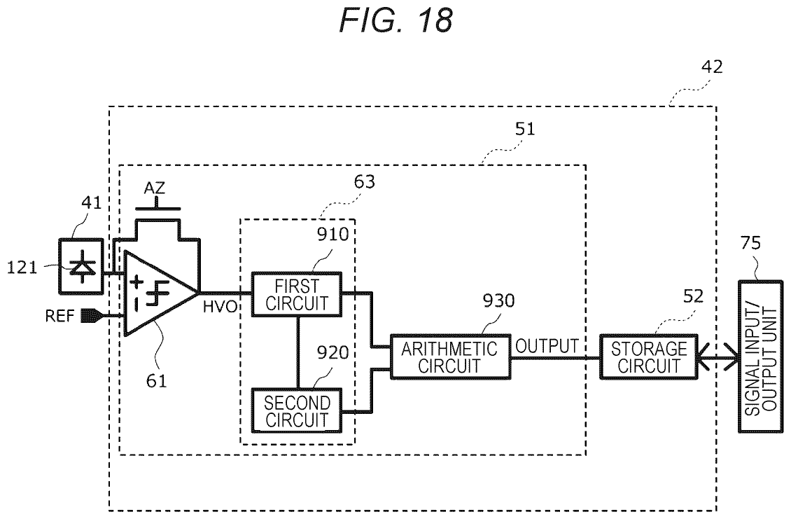

FIG. 16 is a block diagram illustrating an example of a configuration of a timing generator 900 according to a second embodiment. The timing generator is used, for example, in a comparison circuit 51, as will be described later with reference to FIG. 18. However, the present invention is not limited to the comparison circuit 51, and may be used for other circuits.

The timing generator 900 includes a first circuit 910, a second circuit 920, and an arithmetic circuit 930.

The first circuit 910 receives one input signal. The first circuit 910 generates and outputs a first output signal and an activation signal on the basis of the input signal. The first output signal is delayed from the inversion timing of the input signal. The activation signal is a signal for activating the second circuit 920.

The second circuit 920 is activated on the basis of the activation signal, and generates and outputs a second output signal.

The arithmetic circuit 930 generates and outputs a third output signal by calculating the first output signal and the second output signal. The arithmetic circuit performs, for example, a logical operation of the first output signal and the second output signal.

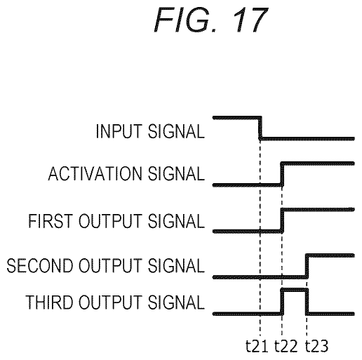

FIG. 17 is a timing chart illustrating an example of operation of the timing generator 900 according to the second embodiment.

In the initial state, the input signal is in the Hi state.

First, at time t21, the input signal becomes Lo. With this arrangement, the first circuit 910 receives the input signal and starts generating the activation signal and the first output signal.

Next, at time t22, the activation signal and the first output signal become Hi. The first circuit 910 outputs the first output signal that is inverted at a first timing (time t22 illustrated in FIG. 17) and the activation signal. Furthermore, the second circuit 920 is activated by the activation signal and start generating the second output signal.

Next, at time t23, the second output signal becomes Hi. The second circuit 920 outputs the second output signal that is inverted at a second timing (time t23 illustrated in FIG. 17) after the first timing.

Furthermore, the arithmetic circuit 930 performs the logical operation on the basis of the first output signal and the second output signal. At time t22, by the first output signal becoming Hi while the second output signal remaining in the Low state, the third output signal becomes Hi. Furthermore, at time t23, by the first output signal remaining in Hi state while the second output signal becoming Hi, the third output signal becomes Low. That is, the arithmetic circuit 930 outputs the third output signal that is inverted at the first timing (time t22 illustrated in FIG. 17) and the second timing (time t23 illustrated in FIG. 17).

As illustrated in FIG. 17, the pulsed third output signal that is in the Hi state in the period from time t22 to time t23 is generated. That is, the timing generator 900 generates, at a timing delayed according to the inversion timing of the input signal, the third output signal having a short pulse width that rises in a period in which the second output signal is delayed from the first output signal.

FIG. 18 is a diagram illustrating an example of a configuration of the comparison circuit 51 and a data storage unit 52 according to the second embodiment.

The comparison circuit 51 includes the first circuit 910, the second circuit 920, and the arithmetic circuit 930. Note that, in the example illustrated in FIG. 18, a pixel circuit 41 and a signal input/output unit 75 are also illustrated. Furthermore, in FIG. 18, a voltage conversion circuit 62 is omitted.

The pixel circuit 41 includes a photodiode 121 that is a photoelectric conversion element. Note that the pixel circuit 41 may be a circuit including a physical quantity detection unit that detects a physical quantity.

The storage circuit 52 corresponds to the data storage unit 52 in FIG. 2.

The input signal is an output signal HVO of a differential input circuit 61. Therefore, the inversion timing of the input signal illustrated in FIG. 17 is a timing at which a physical signal detected by the physical quantity detection unit and a reference signal REF become substantially the same.

FIG. 19 is a circuit diagram illustrating an example of a configuration of the comparison circuit 51 according to the second embodiment.

The differential input circuit 61 includes transistors 81 and 82 forming a differential pair, transistors 83 and 84 constituting a current mirror, a transistor 85 as a constant current source that supplies a current IB according to an input bias current Vb, and a transistor 86 that outputs the output signal HVO of the differential input circuit 61.

The transistors 81, 82, and 85 are constituted of NMOS transistors, and the transistors 83, 84, and 86 are constituted of PMOS transistors.

The first circuit 910 is a first positive feedback circuit (PFB). The first circuit 910 includes transistors 911 and 912 and an inverter 913. The transistors 911 and 912 are constituted of PMOS transistors.

The source of the transistor 91, which is the output terminal of the voltage conversion circuit 62, is connected to the drain of the transistor 912 and one end of the inverter 913. The source of the transistor 911 is connected to a power supply voltage node VDD2. The drain of the transistor 911 is connected to the source of the transistor 912. The other end of the inverter 913, which is the output terminal of the first circuit 910, is connected to the gate of the transistor 912 and one input terminal of the arithmetic circuit 930. An initialization signal INI2 is supplied to the gate of the transistor 911.

The second circuit 920 is a second positive feedback circuit (PFB′), and is connected in series to the first circuit 910 (first positive feedback circuit). That is, the first circuit 910 and the second circuit 920 include the first positive feedback circuit and the second positive feedback circuit connected in series. The second circuit 920 includes transistors 921, 922, and 923 and an inverter 924. The transistor 923 is constituted of a PMOS transistor, and the transistors 921 and 922 are constituted of NMOS transistors.

The source of the transistor 91, which is the output terminal of the voltage conversion circuit 62, is connected to the drain of the transistor 921 and the source of the transistor 923. The source of the transistor 921, which is the output terminal of the second circuit 920, is connected to the drain of the transistor 922, the drain of the transistor 923, one end of the inverter 924, and the other input terminal of the arithmetic circuit 930. The source of the transistor 922 is connected to a low voltage VSS (for example, ground). The other end of the inverter 924 is connected to the gate of the transistor 923. An initialization signal INI3 is supplied to the gate of the transistor 921. An initialization signal INI is supplied to the gate of the transistor 922.

The transistor 921 functions as an activation signal passing unit that passes the activation signal from the first circuit 910 as a leak current.

The arithmetic circuit 930 includes a NOR circuit 931, a NOR circuit 932, and an inverter 933.

One input terminal of the NOR circuit 931 is connected to the output terminal of the first circuit 910. The other input terminal of the NOR circuit 931 is connected to the output terminal of the second circuit 920. The output terminal of the NOR circuit 931 is connected to one input terminal of the NOR circuit 932. The other input terminal of the NOR circuit 932 is supplied with a FORCEVCO signal. The output terminal of the NOR circuit 932 is connected to one end of the inverter 933. An output signal VCO of the arithmetic circuit 930 is output from the other end of the inverter 933.

A voltage Vpfb1 in FIG. 19 is, for example, a voltage of wiring at one end of the inverter 913. A voltage Vpfb2 in FIG. 19 is, for example, a voltage of wiring at one end of the inverter 924.

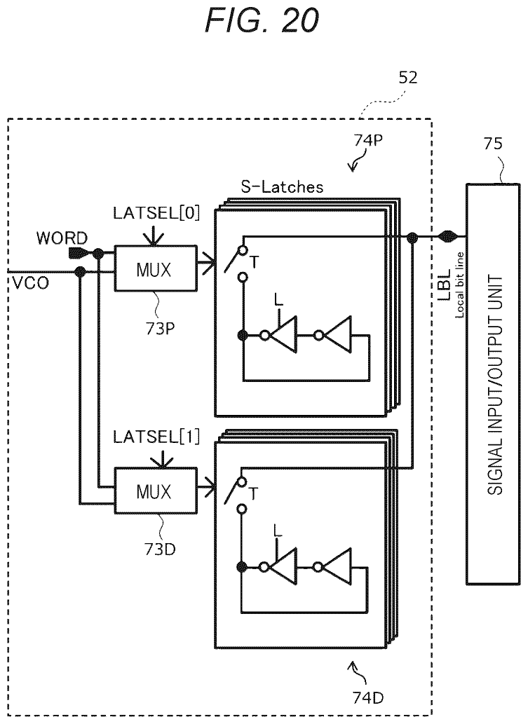

FIG. 20 is a diagram illustrating an example of a configuration of the data storage unit 52 according to the second embodiment.

The output signal VCO of the arithmetic circuit 930 is connected to one input terminal of each of signal control units 73P and 73D which are multiplexers (MUX). A WORD signal is supplied to the other input terminal of each of the signal control units 73P and 73D. Outputs of the signal control units 73P and 73D are supplied to signal storage units 74P and 74D, respectively.

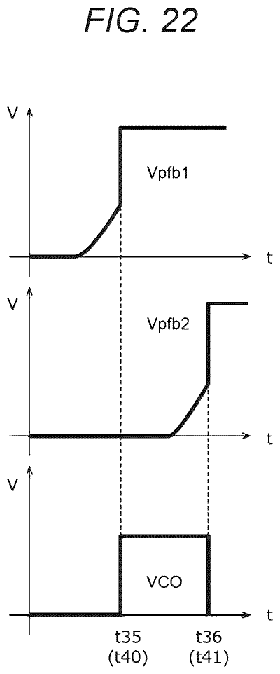

In the writing operation, the signal control units 73P and 73D perform control to store the time code output from the signal input/output unit 75 in the signal storage units 74P and 74D on the basis of the output signal VCO (third output signal) of the arithmetic circuit 930. Furthermore, in the reading operation, the signal control units 73P and 73D output to the signal input/output unit 75, the time code of the time when the output signal VCO (third output signal) of the arithmetic circuit 930 is inverted (transitions to Low), the time code being stored in the signal storage units 74P and 74D, (see FIG. 22).

The signal input/output unit 75, which is a repeater, performs writing to the signal storage units 74P and 74D via a local bit line (LBL).

Writing is performed in the signal storage units 74P and 74D when the switch T (switch Tp and Td) is closed, and data in the signal storage units 74P and 74D is determined when the switch T (switch Tp and Td) is opened.

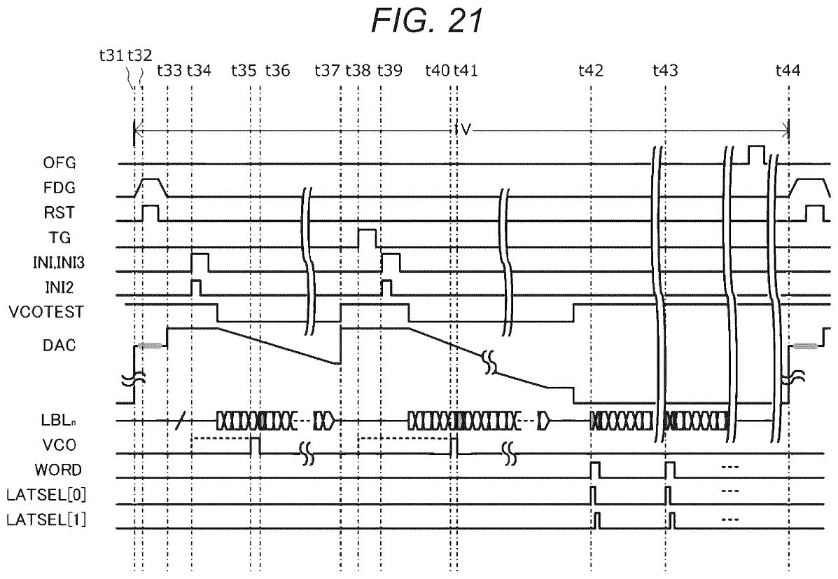

FIG. 21 is a timing chart illustrating an example of operation of the comparison circuit 51 and the data storage unit 52 according to the second embodiment.

Time t31 is a start time of 1 V (one vertical scanning period).

First, at time t32, a reset transistor 124 and a gain control transistor 126 are turned on to cause the charge of a FD 125 to be reset.

At time t33, the reference signal REF is raised to a predetermined voltage.

At time t34, the initialization signals INI, INI2, and INI3 are set to Hi, and the timing generator 900 is set to the initial state. After the initialization signals INI, INI2, and INI3 are returned to Low, comparison between the reference signal REF and a pixel signal SIG (sweep of the reference signal REF) is started. As the reference signal REF is swept, the signal input/output unit 75 transfers the time code.

Note that the voltage Vpfb1 becomes a low voltage VSS, that is, a ground voltage by the initialization signals INI and INI3. Therefore, the second circuit 920 is the second power supply voltage (low voltage VSS) of the first circuit 910 in a period in which the second circuit 920 is not activated.

At time t35 when it is determined that the reference signal REF and the pixel signal SIG have become the same, the output signal VCO is inverted (transitioned to Hi). The signal control unit 73P starts storing the time code in the signal storage unit 74P at the first timing (time t35 illustrated in FIG. 21).

At time t36, the output signal VCO is inverted (transitioned to Low). When the output signal VCO is inverted, time data (N-bit DATA [1] to DATA [N]) of the time when the output signal VCO is inverted is stored in the signal storage unit 74P of the data storage unit 52. The signal control unit 73P stops storing the time code in the signal storage unit 74P at the second timing (time t36 illustrated in FIG. 21).

Detailed operation in a period from time t35 to time t35 will be described with reference to FIG. 22.

FIG. 22 is a diagram illustrating an example of a temporal change of voltage in the comparison circuit 51 according to the second embodiment. Note that FIG. 22 is also an enlarged view of the vicinity of times t35 and t36 in FIG. 21. The upper part of FIG. 22 is a graph illustrating a temporal change of the voltage Vpfb1. The middle part of FIG. 22 is a graph illustrating a temporal change of the voltage Vpfb2. The lower part of FIG. 22 is a graph illustrating a temporal change of the output signal VCO. The horizontal axis in the graph of FIG. 22 indicates time. The vertical axis in the graph of FIG. 22 represents voltage.

As illustrated in FIG. 22, immediately before time t35, the output signal HVO is inverted (transitioned to Hi), the current flows to the first circuit 910, and the voltage Vpfb1 is gradually raised. At time t35, the voltage Vpfb1 exceeds the threshold of the inverter 913. This causes the transistor 912 to be turned on. As a result, the voltage Vpfb1 rapidly rises due to positive feedback and becomes the voltage VDD2. Because the voltage Vpfb1 is Hi and the voltage Vpfb2 remains Low, the output signal VCO is inverted (transitioned to Hi) at time t35.

Furthermore, after time t35, the first circuit 910 functions as a power source of the second circuit 920. Thereafter, the current flowing from the differential input circuit 61 to the first circuit 910 flows as a leak current to the second circuit 920 via the transistor 921 in the off state. This causes the charge to be accumulated in the second circuit 920, and the voltage Vpfb2 is gradually raised. Therefore, the activation signal is the first power supply voltage (voltage VDD2) of the second circuit.

Note that the current charge from the voltage Vpfv1 to the voltage Vpfb2 is determined by leakage of the transistor 921. Therefore, the on voltage is controlled by the Hi voltage of the initialization signal INI3, and the Low voltage of the initialization signal xINI3 is controlled as the off voltage with adjusted leakage.

At time t36, the voltage Vpfb2 exceeds the threshold of the inverter 924. This causes the transistor 923 to be turned on. That is, one end of the inverter 924 is electrically connected to one end of the inverter 913 of the first circuit 910 that functions as a power supply. As a result, the voltage Vpfb2 rapidly rises due to positive feedback and becomes the voltage VDD2. Because both the voltages Vpfb1 and Vpfb2 are Hi, the output signal VCO is inverted (transitioned to Low) at time t36.

The output signal VCO illustrated in FIG. 22 has a short pulse width in a period from time t35 to time t36 as in the third output signal illustrated in FIG. 17.

Thereafter, as illustrated in FIG. 21, at time t37, the reference signal REF is raised to a predetermined voltage.

Subsequently, the circuit is initialized again for acquisition of the D-phase level (signal level).

At time t38, a transfer transistor 123 of the pixel circuit 41 is turned on by a transfer signal TX at Hi, and the charge generated by the photodiode 121 is transferred to the FD 125.

At time t39, the initialization signals INI, INI2, and INI3 are set to Hi, and the timing generator 900 is set to the initial state. Thereafter, after the initialization signals INI, INI2, and INI3 are returned to Low, comparison between the reference signal REF and the pixel signal SIG (sweep of the reference signal REF) is started. As the reference signal REF is swept, the signal input/output unit 75 transfers the time code.

At time t40 when it is determined that the reference signal REF and the pixel signal SIG have become the same, the output signal VCO is inverted (transitioned to Hi). Note that the operation at time t40 is substantially the same as the operation at time t35 illustrated in FIG. 22. The signal control unit 73D starts storing the time code in the signal storage unit 74D at the first timing (time t40 illustrated in FIG. 21).

At time t41, the output signal VCO is inverted (transitioned to Low). When the output signal VCO is inverted, time data (N-bit DATA [1] to DATA [N]) of the time when the output signal VCO is inverted is stored in the signal storage unit 74D of the data storage unit 52. Note that the operation at time t41 is substantially the same as the operation at time t36 illustrated in FIG. 22. The signal control unit 73D stops storing the time code in the signal storage unit 74D at the second timing (time t41 illustrated in FIG. 21).

At times t42 and t43, the WORD signal for controlling the reading timing becomes Hi, and an N-bit latch signal Col [n] (n=1 to N) (not illustrated) is output from a latch control circuit 71 of the data storage unit 52. The data acquired here is the P-phase data of the reset level and the D-phase data of the signal level of the time when the CDS processing is performed.

Furthermore, at each of times t42 and t43, the LATSEL [0] signal becomes Hi, and thereafter, the LATSEL [1] signal becomes Hi. The reset level is acquired by the LATSEL [0] signal, and the signal level is acquired by the LATSEL [1]. The reset level and the signal level are alternately output at the reading timing.

Time t44 is the same state as time t31 described above, and is the next drive of 1 V (one vertical scanning period).

As described above, according to the second embodiment, the first circuit 910 outputs the first output signal obtained by delaying the inversion timing of the input signal and the activation signal for activating the second circuit 920 on the basis of one input signal. With this arrangement, the output of the second circuit 920 can be delayed from the output of the first circuit 910. Therefore, a pulse signal can be generated. Power consumption can be suppressed by using the generated pulse signal for latch control.

### Third Comparative Example

As a third comparative example, a case where the delay signal is not generated will be described.

In the third comparative example, the output signal VCO remains in the Hi state as indicated by a broken line of the output signal VCO illustrated in FIG. 21. In this case, the signal control units 73P and 73D continuously write the signal flowing through the signal input/output unit 75 into the latch while the output signal VCO is Hi. In this case, power consumption increases as the inverters in the signal storage units 74P and 74D continue to operate.

On the other hand, in the second embodiment, the signal control units 73P and 73D perform writing to the signal storage units 74P and 74D in a short period in which the output signal VCO of the arithmetic circuit 930 becomes Hi. That is, in the signal control units 73P and 73D, the switch T (switch Tp and Td) is closed and data is written, and the switch T (switch Tp and Td) is opened and determined. As described above, by closing and opening the switch T in a pulse shape at the timing of inversion of the output signal VCO, unnecessary power consumption in the writing operation of the time code can be reduced. Furthermore, power can be reduced with a circuit having a relatively small area.

### Fourth Comparative Example

The pulse-shaped output signal VCO can also be generated by branching the input signal into two paths, providing a delay circuit in one of the paths, and performing the logical operation on the two branched signals. However, due to characteristic variations or the like, the delay in the delay circuit varies, and there are cases where the width of the output signal VCO cannot be sufficiently obtained. Therefore, it is necessary to carefully design the circuit, and there is a possibility that the circuit scale becomes large.

On the other hand, in the second embodiment, the first output signal and the activation signal are generated from one input signal without having the input signal branched. With this arrangement, the activation of the second circuit 920 is delayed with respect to the output of the first circuit 910, and the delayed second output signal can be more appropriately generated, and the circuit scale is not necessarily increased.

### First Modification of Second Embodiment

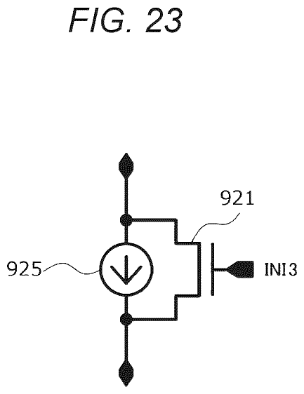

FIG. 23 is a circuit diagram illustrating an example of a configuration of the second circuit 920 according to a first modification of the second embodiment. FIG. 23 illustrates a peripheral configuration of the transistor 921. The first modification of the second embodiment is different from the second embodiment in that a current source 925 is provided.

The second circuit 920 further includes the current source 925. The current source 925 is connected in parallel with the transistor 921. As the current source 925, a current source 925 through which a current slightly leaks is used.

In the first modification of the second embodiment, the leak current passes through the current source 925. As compared with the second embodiment in which the off voltage of the transistor 921 is controlled to control the current value, the settling time of the bias line does not need to be considered.

As in the first modification of the second embodiment, the current source 925 may be provided. Also in this case, the similar effects to those of the second embodiment can be obtained.

### Second Modification of Second Embodiment

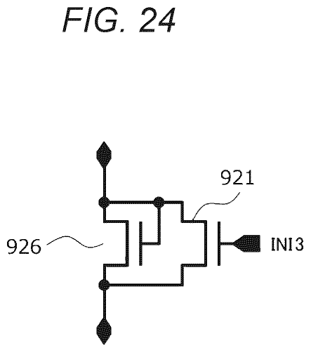

FIG. 24 is a circuit diagram illustrating an example of a configuration of the second circuit 920 according to a second modification of the second embodiment. FIG. 24 illustrates a peripheral configuration of the transistor 921. The first modification of the second embodiment is different from the second embodiment in that a transistor 926 is provided.

The second circuit 920 further includes the transistor 926. The transistor 926 is diode-connected and connected in parallel with the transistor 921. The transistor 926 is constituted of, for example, an NMOS transistor.

In the second modification of the second embodiment, the leak current passes through the transistor 926. As compared with the first modification of the second embodiment using the current source 925, the bias line for the current source becomes unnecessary, and the number of wires can be reduced.

As in the second modification of the second embodiment, the diode-connected transistor 926 may be provided. Also in this case, the similar effects to those of the second embodiment can be obtained.

Note that a high-resistance dummy resistor may be provided instead of the transistor 926.

### Third Modification of Second Embodiment

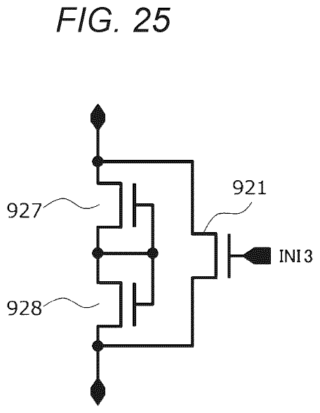

FIG. 25 is a circuit diagram illustrating an example of a configuration of the second circuit 920 according to a third modification of the second embodiment. FIG. 25 illustrates a peripheral configuration of the transistor 921. The third modification of the second embodiment is different from the second modification of the second embodiment in that a diode-connected transistor is further provided.

The second circuit 920 further includes transistors 927 and 928. Each of the transistors 927 and 928 is diode-connected. The transistors 927 and 928 are connected in series, and is connected in parallel with the transistor 921. The transistor 927 is constituted of, for example, a PMOS transistor. The transistor 928 is constituted of, for example, an NMOS transistor.

In the third modification of the second embodiment, the leak current passes through the transistors 927 and 928.

As in the third modification of the second embodiment, the diode-connected transistors 927 and 928 may be provided. Also in this case, the similar effects to those of the second modification of the second embodiment can be obtained.

### Application Example to Mobile Body

The technology according to the present disclosure (the present technology) can be applied to various products. For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

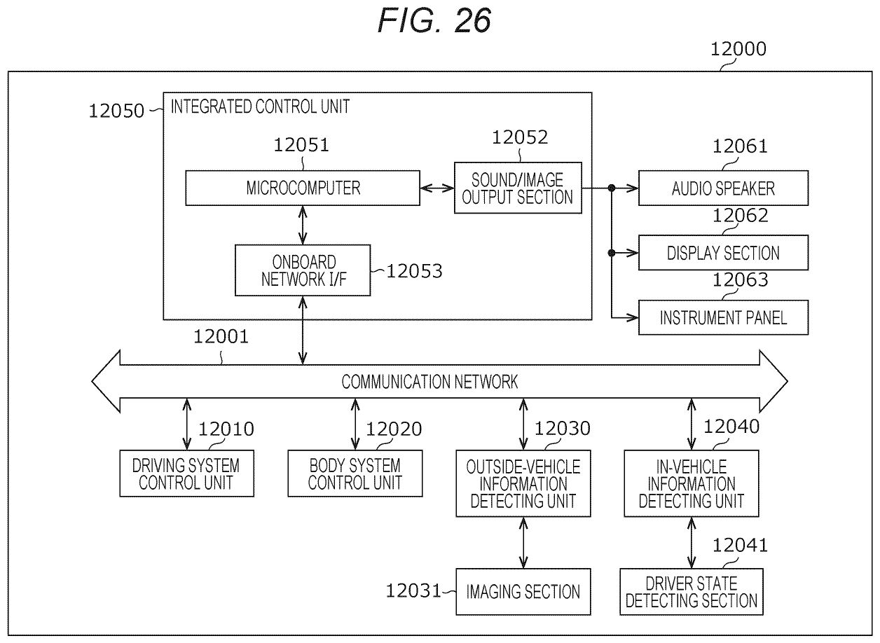

FIG. 26 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example illustrated in FIG. 26, a vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 26, an audio speaker 12061, a display section 12062, and an instrument panel 12063 are illustrated as the output device. The display section 12062 may, for example, include at least one of an on-board display and a head-up display.

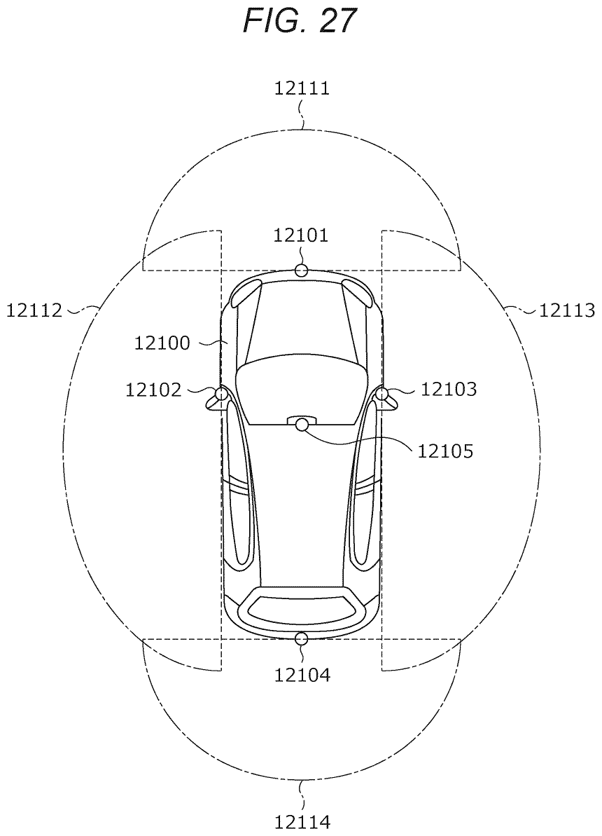

FIG. 27 is a diagram illustrating an example of the installation position of the imaging section 12031.

In FIG. 27, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 27 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging sections 12031, 12101, 12102, 12103, 12104, 12105, and the like among the above-described configurations. Specifically, for example, the solid-state imaging device 1 in FIG. 1 can be applied to these imaging sections. By applying the technology according to the present disclosure to these imaging sections, a high-definition captured image can be obtained with little noise, and thus, high-accuracy control using the captured image can be performed in the mobile body control system.

Note that the present technology may have the following configurations.
(1)

A photodetection element including
a plurality of pixels, in which
each of the plurality of pixels includes:
a physical signal acquisition unit that acquires a physical signal;
a comparison unit that compares a physical signal acquired by the physical signal acquisition unit with a reference signal;
a signal accumulation floating unit that is electrically connected to one end of the comparison unit;
a signal detection unit that is electrically connected to the signal accumulation floating unit and detects a comparison result of the comparison unit;
a signal amplification unit that amplifies a detection result of the signal detection unit;
a signal storage unit that stores a time code;
a signal input/output unit that inputs and outputs a time code; and
a signal control unit that performs control to store a time code output from the signal input/output unit in the signal storage unit on the basis of the comparison result, and outputs, to the signal input/output unit, a time code of the time when the comparison result is inverted, the time code being stored in the signal storage unit, and
at least two or more of the pixels operate in parallel.
(2)

The photodetection element according to (1), further including:
at least two pixel groups each of which detects a physical signal; and
a storage control unit that performs control, for the every pixel group, to store a time code in the signal storage unit and controls whether or not to update a time code stored in the signal storage unit.
(3)

The photodetection element according to (1) or (2), in which
the comparison unit includes a transistor including a gate to which a physical signal acquired by the physical signal acquisition unit is input, a source to which the reference signal is input, and a drain electrically connected to the signal accumulation floating unit,
the comparison unit changes a voltage of the signal accumulation floating unit on the basis of a gate-source voltage of the transistor and a threshold of the transistor to enable the signal detection unit to perform detection, and
the signal detection unit is disposed in a pixel array unit.
(4)

The photodetection element according to (3), further including a capacitor connected between a reference signal generation unit that generates the reference signal and the source of the transistor.
(5)

The photodetection element according to (4), further including a connection unit that is connected between the source of the transistor and the gate of the transistor and electrically connects the source of the transistor and the gate of the transistor at a predetermined timing.
(6)

The photodetection element according to any one of (1) to (5), in which the comparison unit is shared by a plurality of the physical signal acquisition units.
(7)

The photodetection element according to any one of (1) to (6), in which the signal amplification unit is a positive feedback circuit.
(8)

The photodetection element according to any one of (1) to (7), in which the physical signal acquisition unit, the comparison unit, the signal accumulation floating unit, the signal detection unit, the signal amplification unit, the signal control unit, the signal storage unit, and the signal input/output unit are disposed across at least two semiconductor chips.
(9)

The photodetection element according to any one of (1) to (8), in which the signal input/output unit is shared by a plurality of the physical signal acquisition units.
(10)

The photodetection element according to any one of (1) to (9), in which the signal input/output unit includes a flip-flop.
(11)

The photodetection element according to any one of (1) to (9), in which the signal input/output unit includes a tristate inverter.
(12)

The photodetection element according to any one of (1) to (11), in which at least two of the signal storage units are provided.
(13)

The photodetection element according to (12), in which at least two of the signal input/output units are provided correspondingly to respective one of at least two of the signal storage units.
(14)

The photodetection element according to (12) or (13), further including a signal processing unit that performs at least one of subtraction processing between signals stored in at least two of the signal storage units and image processing.
(15)

A timing generator including
a first circuit, a second circuit, and an arithmetic circuit, in which
the first circuit outputs, on the basis of one input signal, a first output signal obtained by delaying an inversion timing of the input signal, and an activation signal that activates the second circuit,
the second circuit is activated on the basis of the activation signal and outputs a second output signal, and
the arithmetic circuit calculates the first output signal and the second output signal to output a third output signal.
(16)

The timing generator according to (15), in which the activation signal is a first power supply voltage of the second circuit.
(17)

The timing generator according to (15) or (16), in which the second circuit is a second power supply voltage of the first circuit in a period in which the second circuit is not activated.
(18)

The timing generator according to any one of (15) to (17), in which the first circuit and the second circuit include a first positive feedback circuit and a second positive feedback circuit that are connected in series.
(19)

An AD converter including:
the timing generator according to any one of (15) to (18);
a signal storage unit that stores a time code; and
a signal control unit that performs control to store a time code in the signal storage unit on the basis of the third output signal.
(20)

The AD converter according to (19), in which
the first circuit outputs the first output signal that is inverted at a first timing,
the second circuit outputs the second output signal that is inverted at a second timing after the first timing,
the arithmetic circuit outputs the third output signal that is inverted at the first timing and the second timing, and
the signal control unit starts storing a time code in the signal storage unit at the first timing, and stops storing a time code in the signal storage unit at the second timing.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

1 Solid-state imaging device
11 Semiconductor substrate
21 Pixel
22 Pixel array unit
23 Time code transfer unit
31 Physical signal acquisition unit
32 Comparison unit
33 Signal accumulation floating unit
34 Signal detection unit
41 Pixel circuit
42 ADC
51 Comparison circuit
52 Data storage unit
35 Signal amplification unit
71 Latch control circuit
72 Latch storage unit
73 Signal control unit
74 Signal storage unit
75 Signal input/output unit
121 Photodiode
900 Timing generator
910 First circuit
920 Second circuit
930 Arithmetic circuit

1. A photodetection element comprising
a plurality of pixels, wherein
each of the plurality of pixels comprises:
a physical signal acquisition unit that acquires a physical signal;
a comparison unit that compares a physical signal acquired by the physical signal acquisition unit with a reference signal;
a signal accumulation floating unit that is electrically connected to one end of the comparison unit;
a signal detection unit that is electrically connected to the signal accumulation floating unit and detects a comparison result of the comparison unit;
a signal amplification unit that amplifies a detection result of the signal detection unit;
a signal storage unit that stores a time code;
a signal input/output unit that inputs and outputs a time code; and
a signal control unit that performs control to store a time code output from the signal input/output unit in the signal storage unit on a basis of the comparison result, and outputs, to the signal input/output unit, a time code of a time when the comparison result is inverted, the time code being stored in the signal storage unit, and
at least two or more of the pixels operate in parallel.

2. The photodetection element according to claim 1, further comprising:
at least two pixel groups each of which detects a physical signal; and
a storage control unit that performs control, for the every pixel group, to store a time code in the signal storage unit and controls whether or not to update a time code stored in the signal storage unit.

3. The photodetection element according to claim 1, wherein
the comparison unit includes a transistor including a gate to which a physical signal acquired by the physical signal acquisition unit is input, a source to which the reference signal is input, and a drain electrically connected to the signal accumulation floating unit,
the comparison unit changes a voltage of the signal accumulation floating unit on a basis of a gate-source voltage of the transistor and a threshold of the transistor to enable the signal detection unit to perform detection, and
the signal detection unit is disposed in a pixel array unit.

4. The photodetection element according to claim 3, further comprising a capacitor connected between a reference signal generation unit that generates the reference signal and the source of the transistor.

5. The photodetection element according to claim 4, further comprising a connection unit that is connected between the source of the transistor and the gate of the transistor and electrically connects the source of the transistor and the gate of the transistor at a predetermined timing.

6. The photodetection element according to claim 1, wherein the comparison unit is shared by a plurality of the physical signal acquisition units.

7. The photodetection element according to claim 1, wherein the signal amplification unit includes a positive feedback circuit.

8. The photodetection element according to claim 1, wherein the physical signal acquisition unit, the comparison unit, the signal accumulation floating unit, the signal detection unit, the signal amplification unit, the signal control unit, the signal storage unit, and the signal input/output unit are disposed across at least two semiconductor chips.

9. The photodetection element according to claim 1, wherein the signal input/output unit is shared by a plurality of the physical signal acquisition units.

10. The photodetection element according to claim 1, wherein the signal input/output unit includes a flip-flop.

11. The photodetection element according to claim 1, wherein the signal input/output unit includes a tristate inverter.

12. The photodetection element according to claim 1, wherein at least two of the signal storage units are provided.

13. The photodetection element according to claim 12, wherein at least two of the signal input/output units are provided correspondingly to respective one of at least two of the signal storage units.

14. The photodetection element according to claim 12, further comprising a signal processing unit that performs at least one of subtraction processing between signals stored in at least two of the signal storage units and image processing.

15. A timing generator comprising
a first circuit, a second circuit, and an arithmetic circuit, wherein
the first circuit outputs, on a basis of one input signal, a first output signal obtained by delaying an inversion timing of the input signal, and an activation signal that activates the second circuit,
the second circuit is activated on a basis of the activation signal and outputs a second output signal, and
the arithmetic circuit calculates the first output signal and the second output signal to output a third output signal.

16. The timing generator according to claim 15, wherein the activation signal includes a first power supply voltage of the second circuit.

17. The timing generator according to claim 15, wherein the second circuit includes a second power supply voltage of the first circuit in a period in which the second circuit is not activated.

18. The timing generator according to claim 15, wherein the first circuit and the second circuit include a first positive feedback circuit and a second positive feedback circuit that are connected in series.

19. An analog to digital (AD) converter comprising:
the timing generator according to claim 15;
a signal storage unit that stores a time code; and
a signal control unit that performs control to store a time code in the signal storage unit on a basis of the third output signal.

20. The AD converter according to claim 19, wherein
the first circuit outputs the first output signal that is inverted at a first timing,
the second circuit outputs the second output signal that is inverted at a second timing after the first timing,
the arithmetic circuit outputs the third output signal that is inverted at the first timing and the second timing, and
the signal control unit starts storing a time code in the signal storage unit at the first timing, and stops storing a time code in the signal storage unit at the second timing.
